(19) United States
(12) Patent Application Publication
(10) Pub. No.: US 2025/0226172 A1
(43) Pub. Date: Jul. 10, 2025

(54) METHOD AND APPARATUS

(71) Applicant: THE UNIVERSITY OF LIVERPOOL, Liverpool (GB)

(72) Inventors: Nigel BROWNING, Liverpool (GB); Daniel NICHOLLS, Liverpool (GB); Alex ROBINSON, Liverpool (GB); Jack WELLS, Liverpool (GB)

(21) Appl. No.: 18/698,918

(22) PCT Filed: Oct. 7, 2022
(86) PCT No.: PCT/GB2022/052545

§ 371 Date: Apr. 5, 2024

(30) Foreign Application Priority Data
Oct. 7, 2021 (GB) 2114359.9
Feb. 10, 2022 (GB) 2201733.9
Jul. 29, 2022 (GB) 2211096.9

(51) Int. Cl. H01J 37/26; H01J 37/22

(52) U.S. Cl. CPC H01J 37/265; H01J 37/222; H01J 2237/226

(57) ABSTRACT

A method of simulating an electron microscopy image of a sample is described. The method implemented by a computer comprising a processor and a memory. The method comprises: obtaining parameters of the electron microscopy, attributes of the sample and respective thresholds of one or more target properties of the simulated electron microscopy image; and computing the simulated electron microscopy image of size [M×N] pixels of the sample using the obtained parameters of the electron microscope and the obtained attributes of the sample, according to the obtained respective thresholds of the one or more target properties of the simulated electron microscopy image.

### FIELD

The present invention relates to simulation of images, for example electron microscopy images.

### BACKGROUND TO THE INVENTION

(Scanning) transmission electron microscopy ((S)TEM), for example, has routinely been shown to be an excellent analytical characterisation tool for scientists, especially those analysing at samples of complex materials [1]. Aberration corrected STEMs are able to produce sub-angstrom electron probes, allowing users, to understand the properties of these complex materials such as their structure, bonding, and composition, as well as more exotic properties like grain boundaries and defects.

Nevertheless, the quantity and quality of data acquired by (S)TEM, for example, is often limited by observer effects on the samples, acquisition times that are too long and/or the data-handling capacity of associated computers. In the example of (S)TEM, long dwell times, high electron beam currents, and/or large amounts of acquired data associated with delivering high resolution and sensitivity may be problematic. To mitigate these problems for (S)TEM, sub-sampling techniques have been developed.

However, given the complexity of the samples, validation of the data acquired by (S)TEM is required, for example to validate the contrast from imaging and diffraction-based methods such as phase-contrast imaging and ptychography.

Hence, there is a need to improve analytical characterisation, for example by electron microscopy.

### SUMMARY OF THE INVENTION

A first aspect provides a method of simulating an electron microscopy image of a sample, the method implemented by a computer comprising a processor and a memory, the method comprising:
obtaining parameters of the electron microscopy, attributes of the sample and respective thresholds of one or more target properties of the simulated electron microscopy image; and
the obtained parameters of the electron microscope and the obtained attributes of the sample, according to the obtained respective thresholds of the one or more target properties of the simulated electron microscopy image.

A second aspect provides a method of controlling an electron microscope, the method implemented, at least in part, by a computer comprising a processor and a memory, the method comprising:
simulating a simulated image of a sample according to the first aspect; and
acquiring an acquired image of the sample comprising controlling the electron microscope using the parameters of the electron microscopy used for the simulated image.

A third aspect provides a method of controlling an electron microscope, the method implemented, at least in part, by a computer comprising a processor and a memory, the method comprising:
providing parameters of the electron microscopy;
acquiring a first acquired image of a sample comprising controlling the electron microscope using the provided parameters of the electron microscopy;
simulating a first simulated image of the sample according to the first aspect;
comparing the first acquired image and the first simulated image;
adapting the parameters of the electron microscopy based on a result of the comparing; and
acquiring a second acquired image of the sample comprising controlling the electron microscope using the adapted parameters of the electron microscopy.

A fourth aspect provides a computer comprising a processor and a memory configured to implement a method according to the first aspect, the second aspect and/or the third aspect.

A fifth aspect provides a computer program comprising instructions which, when executed by a computer comprising a processor and a memory, cause the computer to perform a method according to the first aspect, the second aspect and/or the third aspect.

A sixth aspect provides a non-transient computer-readable storage medium comprising instructions which, when executed by a computer comprising a processor and a memory, cause the computer to perform a method according to the first aspect, the second aspect and/or the third aspect.

A seventh aspect provides an electron microscope including a computer comprising a processor and a memory configured to implement a method according to any of the second aspect and/or the third aspect.

An eighth aspect provides use of sub-sampling in simulating an electron microscopy image of a sample.

### DETAILED DESCRIPTION OF THE INVENTION

According to the present invention there is provided a method, as set forth in the appended claims. Also provided is an electron microscope. Other features of the invention will be apparent from the dependent claims, and the description that follows.

### Simulating Electron Microscopy Image

The first aspect provides a method of simulating an electron microscopy image of a sample, the method implemented by a computer comprising a processor and a memory, the method comprising:
obtaining parameters of the electron microscopy, attributes of the sample and respective thresholds of one or more target properties of the simulated electron microscopy image; and
computing the simulated electron microscopy image of size [M×N] pixels of the sample using the obtained parameters of the electron microscopy and the obtained attributes of the sample, according to the obtained respective thresholds of the one or more target properties of the simulated electron microscopy image.

In this way, the simulated electron microscopy image of the sample is computed having the one or more target properties thereof within their respective thresholds. In other words, the simulated electron microscopy image of the sample has a desired quality (i.e. within permitted thresholds, having sufficient resolution, accuracy and/or precision) while is computed relatively more quickly, having a relatively decreased runtime and/or requiring relatively reduced computer resources. Particularly, the electron microscopy image of the sample is computed via sub-sampling, as described below.

In this way, the simulated electron microscopy image of the sample may be used for real time electron microscopy applications, for example:
i. optimising acquisition of acquired electron microscopy images of samples by providing real-time feedback for parameters during acquisition;
ii. accelerating validation of acquired electron microscopy images of samples;
iii. enabling simulations of STEM video (i.e. a series of images of a sample, for example).

Furthermore, since the computer resources may be relatively reduced, accessibility of simulation of electron microscopy images is facilitated. For example, faster simulations make them more accessible to users on low end machines, and as such this method is more desirable for those that want higher resolution without the need to upgrade existing hardware. Therefore, they can upgrade existing systems without significant costs. In addition, for a user on a microscope, they could quickly simulate their current microscope parameters whilst imaging their desired sample. This would make a move towards AI driven microscopy, improve the user efficiency as any errors could be identified sooner, and also be used as fast dictionary generation for inpainting.

In contrast, conventional methods of simulating electron microscopy images of samples are computationally expensive, having extended runtimes while requiring complex and/or costly computer resources, since the goal of conventional methods of simulating electron microscopy images of samples is to achieve the highest possible quality.

While the method according to the first aspect relates to simulated electron microscopy images of samples, more generally, the method may be applied to simulations of other analytical techniques. Hence, more generally, the first aspect provides a method of simulating an image of a sample due to interaction of electromagnetic radiation and/or particles with the sample (i.e. ab initio, from first principles). It should be understood that the steps of the method according to the first aspect are implemented mutatis mutandis. In other words, while the method according to the first aspect relates to simulated electron microscopy images of samples, the method may be applied mutatis mutandis to other image simulation methods, for example for optical and X-ray techniques as well as simulations for basic physical properties such as band structure. Hence, more generally, the first aspect provides a method of simulating physical properties of a chemical, material and/or biological system and images produced of those systems by interaction with light, X-rays, protons, neutrons and/or electrons or by any other means (i.e. ab initio, from first principles).

The first aspect provides the method of simulating the electron microscopy image of the sample. It should be understood that the electron microscopy image is simulated (i.e. synthesised, generated, calculated) using the computer (i.e. in silico) rather than acquired, for example using an electron microscope. It should be understood that the electron microscopy image is of the sample and hence the image is due to the interaction of electrons with the sample, as defined by the obtained parameters of the electron microscopy and the obtained attributes of the sample. Electron microscopy is known. Electron microscopy images are known, for example transmission electron microscopy images, scanning electron microscopy images and electron diffraction patterns. Typically, electron microscopy images are stored in raw data formats (binary, bitmap, TIFF, MRC, etc.), other image data formats (PNG, JPEG) or in vendor-specific proprietary formats (dm3, emispec, etc.). The electron microscopy images may be compressed (preferably, lossless compression though lossy compression there used to reduce file size by 5% to 10% while providing sub-2 Å reconstruction) or uncompressed.

TIFF and MRC file formats may be used for high quality storage of image data. Similar to MRCs, TIFFs tend to be large in file size with 32-bit MRC and 32-bit TIFF image having similar or identical file sizes. For TIFFs, the disk space may be reduced using native compression. The most common TIFF compressions are the Lempel-Ziv-Welch algorithm, or LZW, and ZIP compression. These strategies use codecs, or table-based lookup algorithms, that aim to reduce the size of the original image. Both LZW and ZIP are lossless compression methods and so will not degrade image quality. Two commonly used photography file formats that support up to 24-bit colour are PNG (Portable Network Graphics) and JPEG (Joint Photographic Experts Group). Electron micrographs typically are in grayscale so may be better suited to 8-bit file formats, which are also used in print media. PNG is a lossless file format and can utilize LZW compression similar to TIFF images. JPEG is a lossy file format that uses discrete cosine transform (DCT) to express a finite sequence of data points in terms of a sum of cosine functions. JPEG format may be avoided for archiving since quality may be lost upon each compression during processing. JPEG has a range of compression ratios ranging from JPEG100 with the least amount of information loss (corresponding to 60% of the original file size for the frame stack and 27% for the aligned sum image) to JPEG000 with the most amount of information loss (corresponding to 0.4% of the original file size for the frame stack and 0.4% for the aligned sum image).

The method is implemented by the computer comprising the processor and the memory. Generally, the method may be performed using a single processor, such as an Intel (RTM) Core 13-3227U CPU @ 1.90 GHz or better, or multiple processors and/or GPUs. Suitable computers are known.

### Parameters of Electron Microscopy

The method comprises obtaining parameters (also known as settings or acquisition parameters) of the electron microscopy. In this way, the simulated electron microscopy image is computed to correspond with an acquired electron microscopy image of the sample. In one example, the parameters include: accelerating voltage, circle aberration coefficient Cs (which determines beam size), ADF detector or equivalent. Other parameters are known. In one example, the parameters additionally and/or alternatively include: condenser lens parameter (for example source spread function, defocus spread function and/or zero defocus reference) and/or objective lens parameters (for example source spread function, defocus spread function and/or zero defocus reference). It should be understood that particular electron microscopes implement particular parameters, subsets and/or combinations thereof.

### Attributes of Sample

The method comprises obtaining attributes (also known as features) of the sample. In this way, the simulated electron microscopy image is computed to correspond with an acquired electron microscopy image of the sample. Generally, the attributes are and/or represent physical and/or chemical characteristics of the sample. In one example, the attributes include chemical composition, structure, crystallography, lattice parameters, thickness, orientation with respect to electron beam and/or microstructure. Other attributes are known. For example, examples of other attributes include, but are not limited to, regional intensity maxima, edges, periodicity, regional chemical composition, or combinations thereof. For example, intensity maxima in the image data may represent peaks associated with particles, molecules, and/or atoms. Edges in the image data may represent particle boundaries, grain boundaries, crystalline dislocations, stress/strain boundaries, interfaces between different compositions/crystalline structures, and combinations thereof. Periodicity in the image data may be related to crystallinity and/or patterned objects. Computational analysis may be performed on the image data including, but are not limited to, a theoretically optimal sparsifying transform technique, an edge detection technique, a Gaussian mixture regression technique, a summary statistics technique, a measures of spatial variability technique, an entropy technique, a matrix decomposition information technique, a peak finding technique, or a combination thereof. Typically, the sample has a thickness of 1 to 20 unit cells. Generally, a patch is at least 2×2 pixels. In one example, the sample is crystalline. In one example, the sample is non-crystalline e.g. amorphous. Non-crystalline samples may be simulated mutatis mutandis.

### Thresholds of Simulated Image

The method comprises obtaining respective thresholds of one or more target properties (i.e. metrics) of the simulated electron microscopy image. In this way, a threshold quality of the simulated electron microscopy image defined. In other words, the quality of the simulated electron microscopy image is sufficient (i.e. for the intended application) and toleranced by the thresholds.

In one example, a target property of the simulated electron microscopy image is a Structural Similarity Index (SSIM) and the respective threshold thereof is at least 60%, preferably at least 70%, more preferably at least 80%, most preferably at least 90%. Generally, the SSIM is a perceptual metric that quantifies the perceptual difference between two similar images, for example image quality degradation caused by processing such as data compression or by losses in data transmission. As applied to the method according to the first aspect, the perceptual difference results from approximation of the simulation, according to the obtained respective thresholds of the one or more target properties of the simulated electron microscopy image. The SSIM is a full reference metric that requires two images from the same image capture: a reference image and a processed image. As applied to the method according to the first aspect, the reference image is thus an ideal or quasi-ideal simulated electron microscopy image, computed according to the target properties of the simulated electron microscopy image (i.e. exact, without permissible thresholds) while the processed image is the simulated electron microscopy image computed according to the obtained respective thresholds of the one or more target properties of the simulated electron microscopy image. It should be understood that a reference image is not provided for each simulated electron microscopy image; rather, reference images are provided for representative simulated electron microscopy images and the computing thereof to achieve the respective thresholds of the one or more target properties applied to computing of other simulated electron microscopy images. In other words, the required computing so as to achieve the respective thresholds of the one or more target properties is learned.

In one example, a target property of the simulated electron microscopy image is a Peak Signal-to-Noise Ratio (PSNR) and the respective threshold thereof is at least 60%, preferably at least 70%, more preferably at least 80%, most preferably at least 90%. PSNR estimates absolute error. PSNR is usually expressed as a logarithmic quantity using the decibel scale. PSNR is commonly used to measure the quality of reconstruction of lossy compression codecs (e.g., for image compression).

In one example, a target property of the simulated electron microscopy image is a mean squared error (MSE) and the respective threshold thereof is at least 60%, preferably at least 70%, more preferably at least 80%, most preferably at least 90%. MSE estimates absolute error. As MSE is derived from the square of Euclidean distance, the MSE is always a positive value with the error decreasing as the error approaches zero. MSE may be used either to assess a quality of a predictor (i.e. a function mapping arbitrary inputs to a sample of values of some random variable), or of an estimator (i.e. a mathematical function mapping a sample of data to an estimate of a parameter of the population from which the data is sampled).

PSNR and MSE both estimate absolute errors. In contrast, SSIM accounts for the strong interdependencies between pixels, especially closely-spaced pixels. These inter-dependencies carry important information about the structure of the objects in the image. For example, luminance masking is a phenomenon whereby image distortions tend to be less visible in bright regions, while contrast masking is a phenomenon whereby distortions become less visible where there is significant activity or “texture” in the image. Hence, SSIM is preferred.

In one example, computing the simulated electron microscopy image comprises one or more processes, as described below, wherein the respective threshold of the SSIM of each process is at least 60%, preferably at least 70%, more preferably at least 80%, most preferably at least 90%.

Resolution and sensitivity/contrast were previously standard STEM image quality metrics but are subjective, being dependent on where measured. Hence, PSNR, MSE and SSIM are preferred. Other quality metrics, including those not requiring a reference, are under development and may be applied mutatis mutandis.

### Computing Simulated Image

The method comprises computing the simulated electron microscopy image of size [M×N] pixels of the sample using the obtained parameters of the electron microscopy and the obtained attributes of the sample, according to the obtained respective thresholds of the one or more target properties of the simulated electron microscopy image. In this way, the simulated electron microscopy image is computed (i.e. calculated by the computer) to correspond approximately with an acquired electron microscopy image of the sample, in which the approximation is defined by the one or more target properties of the simulated electron microscopy image. In other words, the simulated electron microscopy image is a representation of the acquired electron microscopy image, having an acceptable quality for the intended application. That is, simulated electron microscopy image may be different from the acquired electron microscopy image but the differences are statistically and/or analytically acceptable.

In one example, the electron microscopy image is of size [M×N] pixels, wherein 240≤M, N≤10,000, preferably 1,000≤M, N≤5,000, more preferably 2,000≤M, N≤4,000.

TABLE 1
Example electron microscopy image of size [M × N] pixels.

| M | N |
|---|---|
| 320 | 240 |
| 640 | 480 |
| 1024 | 768 |
| 1280 | 1024 |
| 720 | 756 |
| 1280 | 720 |
| 1920 | 1080 |
| 4096 | 2160 |
| 3996 | 2160 |
| 4096 | 1716 |
| 3840 | 2160 |
| 7680 | 4320 |
| 3840 | 1644 |
| 3838 | 3710 |
| 7676 | 7420 |

In one example, the electron microscopy image is grayscale, for example 8-bit, 16-bit, 24-bit or 32-bit, preferably 8-bit.

Generally, the electron microscopy image is computed via sub-sampling. Herein, three example processes of sub-sampling to reduce the run-time of electoral microscopy, for example STEM, simulations are described. The first process is based on sparse sub-sampling, the second process is related to the number of frozen phonon configurations (FPC) used and the third process is based on optimisation of the maximum reciprocal space vector that contributes to the simulated electron microscopy image. Other processes are known. It should be understood that these processes may be used individually or in combination (in series and/or in parallel).

### Sparse Sub-Sampling

The first process is based on sparse sub-sampling, in which a sparse set of sub-images is simulated and the simulated electron microscopy image reconstructed therefrom. Particularly, the inventors have developed a process of patch acquisition, for example random patch acquisition, in order to effectively (analogous to) sub-sample the probe. This first process is analogous to probe sub-sampling used in Compressive Sensing (CS) applied to STEM, in which a sub-sampled electron microscopy image is acquired, in which a sampling percentage is acquired through random scan points of the sample. See, for example, US2019043690A1, the subject matter of which is incorporated herein in entirety by reference.

In one example, computing the simulated electron microscopy image of size [M×N] pixels of the sample comprises:
calculating a sparse set of S simulated sub-images, including a first sub-image of size [a×b] pixels wherein a, b∈[2, min {M, N}], of the sample; and
reconstructing the simulated electron microscopy image of size [M×N] pixels of the sample using the sparse set of S simulated sub-images of the sample.

In more detail, as shown in FIG. 4A, the full set of pictures is generated from the sample area and each patch is indexed. The required set of pictures to be simulated is formed from the sampling pattern and sampling percentages selected. The required pictures are simulated and subsequently, each simulated purchase inserted back to its index position on the final image. This generates a sub-sampled, simulated image of the sample. In more detail, an image of size [M×N] pixels can be broken down into a set of patches size [a×b] (FIG. 4C). Each patch is then indexed and creates a vector of patches which can be individually simulated depending on the desired scan pattern and sampling percentage. The simulated patches are then restored back into their respective index position (FIG. 4D), and those which are not simulated are set to a value of zero. The workflow forms a sub-sampled, simulated image (FIG. 4A).

Hence, for a desired sampling area, resolution and sampling percentage, a random selection (for example) of [a×b] pixel patches are simulated individually and then restored in an output image containing only a percentage of the total area which would have been simulated in a full simulation. The patches are treated independently, such that the result of simulating one patch has no influence upon any other patch. FIG. 4B is a pseudo code demonstrating this process.

Generally, a simulated image of size [M×N] pixels is constructed from a series of simulated sub-images (also known patches) of size [a×b] pixels wherein a, b∈[2, min {M, N}], as shown in FIG. 4C and FIG. 4D. The number of sub-images required to be simulated is defined by the desired sampling percentage, which in turn is defined by the respective thresholds of one or more target properties of the simulated electron microscopy image.

FIG. 4E shows a sub-sampled simulation using [2×2] patches over a 20% desired sampling percentage and FIG. 4F shows the full simulated counterpart thereof (i.e. reference image).

A simulated image may be directly sub-sampled using MULTEM [2] open-source software in Matlab by a process of discrete patch simulation. MULTEM is a GPU parallelised software which uses a Matlab MEX interface running C++ with CUDA in the background. software is known. The scan area is defined in terms of Angstroms (Å), hence when simulating a sub-image (also known as a patch), the area of that sub-image is called, then simulated, and then saved into a matrix of simulated data. The resulting simulated electron microscopy image is the collection of simulated sub-images restored to their respective positions, with sub-image that have not been simulated set at a value of zero. Other software is known. For example, Prismatic software uses a method termed plane-wave reciprocal-space interpolated scattering matrix (PRISM) which can significantly reduce the run-time of simulation. The method is similar to the multislice method, but instead makes use of Fourier interpolation of the scattering matrix.

Once the sub-sampled simulation has been generated, it is then reconstructed, for example using the Beta-Process Factor Analysis via Expectation Maximisation (BPFA-EM) algorithm. Any dictionary learning algorithm capable of generating a dictionary from sub-sampled data followed by a sparsity pursuit algorithm is capable of image reconstruction given sufficient input parameters. A full simulation may also be performed to provide a reference image and hence quality metrics of the process, as described previously. The metrics used in each of the methods are the Matlab functions structural similarity (SSIM), and peak signal-to-noise ratio (PSNR).

Given that MULTEM calculates the simulation of each sub-image (also known as a patch) on a GPU(s), the data then must be transferred from GPU memory to CPU memory. As a result, for sub-images which are not computationally large, the dwell time for data transfer has a greater influence upon the simulation run-time of each sub-image. This means that as sub-images get computationally larger, the percentage of the run-time for the sub-sampled simulation compared to the full simulation tends towards the desired sampling percentage, however, will always been marginally greater than this value. That is, as patch size [a×b] pixels tends to the output image size [M×N] pixels, run time percentage tends to sampling percentage.

In one example, the method comprises sampling the sparse set of S simulated sub-images of the sample, for example random sampling, line hop sampling, adaptive sampling, Poisson disk sampling, spiral sampling or radial sampling. Other sampling types (also known as patterns) are known. Different data acquisition methods will better suit different sampling types, depending on how the data are distributed. Given that this method is not limited by beam damage or other acquisition effects, a sampling pattern (or patch selection set) could be designed in such a way that reconstruction quality is maximised without any computational cost. For the exemplary embodiments described herein, random sampling is used.

In one example, calculating the sparse set of S simulated sub-images of the sample comprises independently calculating the sparse set of S simulated sub-images of the sample.

It should be understood that the set of S simulated sub-images, including the first sub-image of size [a×b] pixels, is a sparse set, wherein the total area (and/or number of pixels) of the set of S simulated sub-images, including the first sub-image of size [a×b] pixels, is less than the area (and/or number of pixels) of the electron microscopy image of size [M×N] pixels. In one example, the total area (and/or number of pixels) of the set of S simulated sub-images, including the first sub-image of size [a×b] pixels, is in a range from 0.1% to 90%, preferable in a range from 1% to 75%, more preferably in a range from 10% to 50%, most preferably in a range from 15% to 35% of the area (and/or number of pixels) of the electron microscopy image of size [M×N] pixels.

It should be understood that S is a natural number. In one example, set of S simulated sub-images includes S simulated sub-images, wherein S≥1, preferably wherein 1≤S≤10,000, more preferably wherein 10≤S≤5,000, most preferably wherein 100≤S≤1,000. In one example, each sub-image of the set of S simulated sub-images has a size [a×b] pixels. Preferably, the sub-images are the same size to maximise dispersion of sampling. In one example, each sub-image of the set of S simulated sub-images has a different size. In one example, the sub-images do not mutually overlap. In one example, at least some of the sub-images mutually overlap. Preferably, the sub-images do not mutually overlap since mutual overlapping decreases the efficiency and sparsity. In one example, the sub-images are not mutually adjacent. In one example, at least some of the sub-images are mutually adjacent. Preferably, the sub-images are not mutually adjacent since mutual adjacency decreases the efficiency and sparsity.

It should be understood that a, b are natural numbers. In one example, a=b. In one example, a≈b. In one example, 2≤a, b≤10, preferably 2≤a, b≤5, more preferably 2≤a, b≤3. In one preferred example, a=b=2.

### Optimising Number of Frozen Phonon Configurations

A second method to decrease the run-time of STEM simulations (which can be used in conjunction with the sub-sampling process) is to optimise, for example reduce, the number of frozen phonon configurations, using the frozen-phonon model.

For each slice of the multislice calculation, a random set of frozen phonon configurations are selected (see FIG. 6) and simulated, and then the intensity is averaged out at the end for all of the configurations in the final image [2]. As a result, there is a compromise between accuracy and run-time since a simulation must be performed for each possible random set of configurations. Therefore, since we wish to reduce the number of simulations to a minimum, we want to minimise the number of configurations that are necessary to give functionally similar results to data that has many configurations. When this is used with the sub-sampling technique, a new set of configurations is used. As a result, for the total sub-sampled simulation, the number of configurations is proportional to the number of patches.

For thicker samples, the variance in the output image is reduced given there are more slices to calculate and to average out. There exists a number of configurations which beyond that number, the gradient of the image improvement falls below one, i.e. diminishing returns for increasing number of configurations. This number is inversely proportional to the thickness of the sample. Hence, if the number of configurations is sufficiently large given the thickness of the sample, the output image is functionally similar to the output for many configurations. It is important to note that this manipulation is intended to increase speed and not accuracy and for complex samples containing defects or dopants, a larger number of configurations is generally recommended to account for the larger atomic position uncertainty.

In one example, computing the simulated electron microscopy image of size [M×N] pixels of the sample comprises:
estimating thermal-diffuse scattering through the sample including modelling the thermal-diffuse scattering through a series of n slices, wherein n≥1, of the sample having a thickness t, wherein modelling the thermal-diffuse scattering through the first slice comprises selecting a set of p frozen phonon configurations, wherein p≥1, thereof.

It should be understood that t is a real number, typically measured in Å or nm.

It should be understood that n is a natural number. In one example, n∝t. That is, the number n of slices is directly proportional to the thickness t of the sample. In other words, as the thickness t of the sample is increased, the number n of slices is also increased in direct proportion to account for the increased thickness. Generally, decreasing the number n of slices decreases a runtime of the computing but degrades a quality of the simulated electron microscopy image while increasing the number n of slices increases a runtime of the computing but improves the quality of the simulated electron microscopy. In one example, 1≤n≤50, preferably 2≤n≤25, more preferably 3≤n≤10.

It should be understood that p is a natural number. In one example, p∝1/t. That is, the number p of frozen phonon configurations is inversely proportional to the thickness t of the sample. In other words, as the thickness t of the sample is increased, for example towards a bulk material, the number p of frozen phonon configurations may be decreased in direct proportion since the increased thickness may be sufficiently well represented by a simplified frozen phonon configuration. Generally, decreasing the number p of frozen phonon configurations decreases a runtime of the computing but degrades a quality of the simulated electron microscopy image while increasing the number p of frozen phonon configurations increases a runtime of the computing but improves the quality of the simulated electron microscopy. In one example, 1≤p≤50, preferably 2≤p≤25, more preferably 3≤p≤10.

In one example, p∝S. That is, as the number S simulated sub-images is increased, the number p of frozen phonon configurations it is also increased in direct proportion, so as to better represent the different sub images. In this way, a quality of the simulated electron microscopy image is improved.

### Optimising Maximum Reciprocal Space Vector

Similar to reducing the number of frozen phonon configurations, the maximum reciprocal space vector, or the simulation space which contributes to the final solution in the simulation, may be reduced. Optimising this number reduces the number of calculations required per multislice calculation, and hence reduces the total run-time of the simulation. FIG. 9 demonstrates how changing the bandwidth limit for the reciprocal space vector impacts the resulting simulated images. Minimising this limit allows simulations to be performed faster, without detrimental impacts upon the result.

For a radial detector with an outer angle of θₒᵤₜₑᵣ, the maximum reciprocal space vector kₘₐₓ that is incident on the detector will be θ/λ where λ is the wavelength of the electron. Therefore, we can calculate the maximum simulation box size required n to cover the entire detector, reducing the number of calculations required. This is demonstrated in FIG. 9.

In more detail, the maximum reciprocal space vector kₘₐₓ is given by:

$${k}_{m ax} = 2 \times \frac{α}{λ} = max [ \frac{{n}_{x , y}}{2 {l}_{x , y}} ]$$

where α is the semi-convergence angle, λ is the wavelength of the electron, n_{x,y} is the ‘simulation box’ and l_{x,y} is the sample dimensions.

The ‘simulation box’ n_{x,y} is related to the outer angle (this is outer angle) angle θ outer of the detector by:

$${n}_{xy} = \frac{2 sin ( {θ}_{outer} )}{λ} {l}_{x , y} ≅ \frac{2 {θ}_{outer}}{λ} {l}_{x , y}$$

Hence, the maximum reciprocal space vector kₘₐₓ is given by:

$${k}_{m ax} = \frac{{θ}_{outer}}{λ}$$

In one example, computing the simulated electron microscopy image of size [M×N] pixels of the sample comprises:
determining a number of reciprocal space vectors contributing to the simulated electron microscopy image of size [M×N] pixels of the sample; and the determined number of reciprocal space vectors.

In one preferred example, computing the simulated electron microscopy image of size [M×N] pixels of the sample comprises:
determining a maximum reciprocal space vector kₘₐₓ contributing to the simulated electron microscopy image of size [M×N] pixels of the sample; and
computing the simulated electron microscopy image of size [M×N] pixels of the sample using the determined maximum reciprocal space vector kₘₐₓ.

That is, the maximum reciprocal space vector kₘₐₓ required to cover the detector sufficiently that optimises run-time with acquired data is determined.

In one example, the method comprises finding the smallest possible maximum reciprocal space vector such that the resulting simulation is functionally identical to performing a full simulation with a maximum reciprocal space vector far greater than the value required to cover the detector.

### Resource Usage

In one example, the obtaining comprises obtaining a computer resource budget (for example, a resource usage limit, a maximum runtime) and the computing comprises computing according to the obtained computer budget. In this way, the simulated electron microscopy image is computed within the obtained computer resource budget, for example to meet a maximum runtime.

In one example, the method comprises forecasting a computer resource usage of the computing, modifying the obtained respective thresholds of one or more target properties of the simulated electron microscopy image based on a result of comparing the obtained computer resource budget and the forecast computer resource usage and computing according to the modified respective thresholds of the one or more target properties of the simulated electron microscopy image. This way, the simulated electron microscopy image is computed adaptively within the obtained computer resource budget, for example to meet a maximum runtime.

Updating Parameters, Attributes and/or Thresholds

In one example, the method comprises:
updating, for example iteratively, recursively and/or repeatedly, the parameters of the electron microscopy, the attributes of the sample and/or the respective thresholds of the one or more target properties of the simulated electron microscopy image; and
computing the simulated electron microscopy image of size [M×N] pixels of the sample using the updated parameters of the electron microscopy and/or the updated attributes of the sample, according to the updated respective thresholds of the one or more target properties of the simulated electron microscopy image.

In this way, the simulated electron microscopy image is optimised since the parameters of the electron microscopy, the attributes of the sample and/or the respective thresholds of the one or more target properties of the simulated electron microscopy image are updated, for example iteratively, recursively and/or repeatedly, so as to improve the quality of the simulated electron microscopy image within the respective thresholds of the one or more target properties and/or within a computer resource budget, as described previously.

### Inpainting

In one example, the method comprises inpainting. For example, an inpainting algorithm may be used to fill in gaps in the sub-sampled data, with missing information inferred from the sub-sampled data through a combination of a dictionary learning algorithm and a sparsity pursuit algorithm. A common class of inpainting algorithms involve sparse dictionary learning. Dictionary learning algorithms produce a dictionary of basic signal patterns, which is learned from the data, which is able to via a sparse linear combination with a set of corresponding weights. This dictionary is then used in conjunction with a sparse pursuit algorithm to inpaint the pixels of each overlapping patch which when combined form a full image.

### Targeted Sampling Strategy

The inventors have shown that the run-time of STEM simulations can be significantly reduced with functionally identical results through signal compression methods. The spatial acquisition, reciprocal space acquisition, and number of frozen phonon configurations may be reduced and then reconstructed to form the full image using an inpainting algorithm. Herein is described and demonstrated a new method that may significantly further improve the efficiency through a targeted sampling strategy, optionally along with a new approach to independently sub-sample each frozen phonon layer. The results show that it is possible to achieve 92% similarity with only 3% spatial sampling, and the potential to reduce run-times by factors of up to 400× without significant loss of simulation quality.

One of the initial steps to improving the efficiency of compressed simulations was to consider the sampling strategy used to acquire the spatial signal. According to compressive sensing (CS) theory, purely random sampling is the best which has been used in previous work. However, given that high resolution STEM simulations contain a significant amount of ‘vacuum’ space, the number of pixels sampled which contained no signal was disproportionate. This meant that too much time was spent sampling on vacuum space relative to more important features, such as atoms.

The luxury of STEM simulations is that one must inform the software of atom locations, which for MULTEM is a file containing atomic coordinates, atomic number, charge and so on. Therefore, it is proposed that this file could also be used as a method to form a targeted sampling mask which prioritises sampling on atoms, as opposed to a purely random approach. However, the sampling is not purely targeted, but also includes some bias, R, which allows any location to be sampled with some likelihood, S. This essentially makes the mask a layer of purely random sampling (required by CS theory), and purely targeted based on the atomic number, Z, to optimise the sampling strategy.

The second step towards improving the efficiency of STEM simulation is to optimise how the frozen phonon model can be adapted through a targeted sampling method. The frozen phonon model is used to account for thermal diffuse scattering within the sample, and essentially takes a snapshot of the sample at some given time where the atom locations are slightly displaced from their equilibrium position depending on the Debye Waller factor (DWF) of the atom. Each snapshot of atom positions is known as a frozen phonon configuration (FPC) and the more configurations considered, generally the more accurate the simulation is, given the final simulation is the average of all simulations over varying configurations.

In practice, it was shown in previous work that beyond some number of configurations (thickness dependent), the improvement in simulation quality diminished, however the run-time scaled linearly. Therefore, for the purpose of speeding up simulations, it was better to limit the number of configurations at the point where the quality improvement begins to diminish.

However, consider sampling at a location where there is no atom. Here the number of configurations used is relatively insignificant to the intensity of the pixel at that location, and therefore to continue sampling this position would be time inefficient. It would be better to sample on atoms more frequently where the frozen phonon approximation matters more. This can be achieved by using a different targeted mask for each FPC rather than using the same mask each time. This will also increase the net sampling of the final simulation as the pixel values are averaged in the final step, as well as reducing the total sampling ratio required for each independent configuration.

These two methods, for example when used in conjunction, can yield a final simulation that still respects the frozen phonon approximation and its importance, but also reduces the overall sampling so that run-time decreases, and the net sampling increases if the parameters are sufficient.

The spatially subsampled simulations are reconstructed through an inpainting algorithm, for example comprising two key parts-a (blind) dictionary learning algorithm, followed by a sparse coding algorithm. The image recovery problem may be turned into a Bayesian dictionary learning problem based on the Beta Process Factor Analysis (BPFA) developed in Paisley 2009 and Zhou 2009, for example. Readers are referred to Nicholls 2022 for more details on the algorithm which are omitted here.

In this way, it is possible to significantly reduce the sampling ratio per layer and still achieve functionally identical results by combining a targeted sampling strategy with a varying mask for each FPC.

In one example, the method comprises forming a targeted sampling mask (i.e. masking using the targeted sampling mask) which prioritises sampling on atoms of the atoms, using atom locations thereof, wherein the targeted sampling mask includes a bias, R, which allows an atom location to be sampled with a likelihood, P, as described previously.

In one example, the method comprises using a different targeted sampling mask for each frozen phonon configuration, as described previously. It should be understood that the set of p frozen phonon configurations is as described previously, wherein p≥2.

### Compressed Simulations Via Virtual Detectors

A virtual detector is equivalent to a radial detector in a STEM. The virtual detector is the integration of binary signals in taken from the convergent beam electron diffraction (CBED) pattern on the pixelated detector.

FIG. 21 shows applying a virtual detector to CBED (left to right), by way of example. The intensity on the diagonal pattern filled ring is integrated to have an equivalent to a HAADF.

Virtual detectors may be applied to compressed simulations by spatially sub-sampling the simulations and collecting a finite number of CBEDs that correlate to certain probe positions.

Then, a sub-sampled image may be formed which corresponds to a certain scattering range using a virtual detector. This allows for all standard STEM image types to be formed from one data set. Furthermore, this may be applied to the simulation of ptychography and other 4D-STEM methods.

The novelty of this is the method of subsampling probe positions to form a subsampled 4D-STEM data set. If the number of probe positions covers a real space of [x, y], and the size of each CBED covers a reciprocal space of [kₓ, k_{y}], and we have a sampling ratio of S, then the total data set is reduced by factor of 1/S. This makes the simulation faster, but also reduces the data storage required, as well as providing a useful tool for real 4D-STEM acquisition.

In one example, the method comprises spatially sub-sampling the simulated electron microscopy image, collecting convergent beam electron diffraction, CBED, patterns and forming a sub-sampled image, using a virtual detector (i.e. using the collected CBED patterns), as described previously.

### Controlling Electron Microscope

The second aspect provides a method of controlling an electron microscope, the method implemented, at least in part, by a computer comprising a processor and a memory, the method comprising:
simulating a simulated image of a sample according to the first aspect; and
acquiring an acquired image of the sample comprising controlling the electron microscope using the parameters of the electron microscopy used for the simulated image.

In this way, simulation of the image of the sample may be used to establish, for example optimise, the parameters of the electron microscopy in silico before subsequently acquiring the image of the sample using the electron microscope. In this way, a duty cycle of the electron microscope and/or a quality of the acquired image may be enhanced while damage to the sample reduced.

It should be understood that the acquired image of the sample is a measured image, for example acquired using a detector of the electron microscope.

The third aspect provides a method of controlling an electron microscope, the method implemented, at least in part, by a computer comprising a processor and a memory, the method comprising:
providing parameters of the electron microscopy;
acquiring a first acquired image of a sample comprising controlling the electron microscope using the provided parameters of the electron microscopy;
simulating a first simulated image of the sample according to the first aspect;
comparing the first acquired image and the first simulated image;
optionally, adapting the parameters of the electron microscopy based on a result of the comparing; and
optionally, acquiring a second acquired image of the sample comprising controlling the electron microscope using the adapted parameters of the electron microscopy.

In this way, the first acquired image of the sample is acquired and compared with the first simulated image, for example for validation thereof. Validation mitigates aberrations and/or artefacts due to the electron microscopy, for example due to incorrect parameters of the electron microscopy, operational errors and/or peculiarities of the sample. Optionally, based on a result of the comparing, the parameters of the electron microscope are adapted and the second acquired image of the sample is acquired, using the adapted parameters. That is, the parameters of the electron microscope are optimised or refined for the sample. In this way a quality of the second acquired image may be further enhanced while damage to the sample controlled.

In one example, the method comprises:
simulating a second simulated image of the sample according to the first aspect using the adapted parameters of the electron microscopy and;
comparing the first acquired image and/or the second acquired image and the second simulated image.

In this way, the first acquired image and/or the second acquired image may be validated against the second simulated image.

### Computer, Computer Program, Non-Transient Computer-Readable Storage Medium

The fourth aspect provides a computer comprising a processor and a memory configured to implement a method according to the first aspect, the second aspect and/or the third aspect.

The fifth aspect provides a computer program comprising instructions which, when executed by a computer comprising a processor and a memory, cause the computer to perform a method according to the first aspect, the second aspect and/or the third aspect.

The sixth aspect provides a non-transient computer-readable storage medium comprising instructions which, when executed by a computer comprising a processor and a memory, cause the computer to perform a method according to the first aspect, the second aspect and/or the third aspect.

### Electron Microscope

The seventh aspect provides an electron microscope including a computer comprising a processor and a memory configured to implement a method according to any of the second aspect and/or the third aspect.

### Use

The eighth aspect provides use of sub-sampling in simulating an electron microscopy image of a sample, for example as described with respect to the first aspect to the seventh aspect.

### Definitions

Throughout this specification, the term “comprising” or “comprises” means including the component(s) specified but not to the exclusion of the presence of other components. The term “consisting of” or “consists of” means including the components specified but excluding other components.

The optional features set out herein may be used either individually or in combination with each other where appropriate and particularly in the combinations as set out in the accompanying claims. The optional features for each aspect or exemplary embodiment of the invention, as set out herein are also applicable to all other aspects or exemplary embodiments of the invention, where appropriate. In other words, the skilled person reading this specification should consider the optional features for each aspect or exemplary embodiment of the invention as interchangeable and combinable between different aspects and exemplary embodiments.

### BRIEF DESCRIPTION OF THE DRAWINGS

For a better understanding of the invention, and to show how exemplary embodiments of the same may be brought into effect, reference will be made, by way of example only, to the accompanying diagrammatic Figures, in which:

FIG. 1 schematically depicts a method according to an exemplary embodiment.

FIG. 2 schematically depicts a method of a sub-sampled simulation with three different (modular) processes according to an exemplary embodiment.

FIG. 3 shows reconstruction of a sub-sampled simulation for ZK-5 where only the space is compressed (neither the number of FPCs or maximum reciprocal space vector are optimised).

FIG. 4A shows a workflow to form a sub-sampled, simulated image for ZK-5; FIG. 4B is Pseudo Code for Random Patch Acquisition. FIG. 4C schematically depicts an image of size [M×N] pixels broken down into a set of patches size [a×b]. Each patch is then indexed and creates a vector of patches which can be individually simulated depending on the desired scan pattern and sampling percentage. FIG. 4D schematically depicts the simulated patches restored back into their respective index position, and those which are not simulated are set to a value of zero. FIG. 4E is an example of a Full Simulation. FIG. 4F is the Sub-sampled Simulated Counterpart of FIG. 4E.

FIG. 5A shows the effect of sampling percentage a reconstruction quality. Beyond a certain sampling percentage (depending on the sampling regime), the increase of reconstructed image quality decreases. FIG. 5B shows images generated in analysis of subsampling the simulation.

FIG. 6 schematically depicts frozen phonon configurations.

FIG. 7 shows how varying the number of frozen phonon configurations (the number above each image) effects the output simulation for graphene sheets. Each SSIM and PSNR value is taken with respect to the maximum number used (in this case 64).

FIG. 8A shows the result of increasing the number of frozen phonon configurations upon run-time and image quality metrics. PSNR stops since its value is infinite when the reference image is the same as the input. FIG. 8B shows images generated in analysis of optimising the number of frozen phonon configurations.

FIG. 9 is a demonstration of how the increase in simulation box sampling has diminishing returns on the output image for ZK-5. Beyond the length of the simulation box being equal to the outer diameter of the detector (upper middle), the simulations are functionally identical (lower middle, lower right). In more detail, FIG. 9 is a demonstration of how the simulation box, or maximum reciprocal space vector changes the outcome of the simulation. When it is too small, the electrons which would have scattered to angles incident upon the detector would not contribute, and beyond the limit of the detector, the improvement in simulation is diminishing.

FIG. 10A is a demonstration of optimising the number of contributing reciprocal space vectors.

FIG. 10B shows images generated in analysis of optimising the maximum reciprocal space vector.

FIG. 11 shows the sub-sampled simulation (top) of ZK-5, the simulation box with an optimised maximum reciprocal space vector (middle), and the dictionary generated using BPFA-EM from the sub-sampled data (bottom). The images have been rescaled for illustrative purposes only.

FIG. 12 shows a Compressed Simulation or Reconstructed Image (left), Structural Similarity Map (middle) and Full Sampled Simulation or Reference Image (right) of ZK-5.

FIG. 13 is an example of LiMn₂O₄ (LMO) reconstructed using a dictionary from silicon dumbbells image, with reduced k-vector sampling, reduced FPCs and 20% subsampling.

FIG. 14 summarises data used in FIGS. 5A, 8A and 10A.

FIG. 15 shows details of the sub-sampled simulation of ZK-5.

FIG. 16 shows a structure image of a unit cell of ZK-5.

FIG. 17 shows The method of forming a targeted sampling mask for compressed simulations. The file for atomic locations is loaded, it is then passed through a code which generates a sampling space map of atom locations where the relative radii is on the order of Angstroms, and the intensity of each atom is location is proportional to its atomic number. The space map is then used in conjunction with a random bias, R, to form a targeted sampling mask through a sampling function, f(Z,R). If the value of R is 1, then the mask is purely random, if it is 0, then the mask is purely targeted.

FIG. 18 shows the difference between using a varying targeted sampling mask (a) for each FPC and using the same targeted sampling mask (b) for each FPC on the final output of the simulation. The net sampling increases significantly with a random bias value of 0.6 without any extra increase in the run-time of the overall simulation.

FIG. 19 shows image quality metrics for the methods in combination over varying sampling ratios. The results show that at low sampling ratios per layer (<10% sampling), up to 95% similarity can be achieved with respect to the reference. This is significantly better than the previous method, where 20% sampling was required in order to achieve similar results.

FIG. 20 schematically depicts 4D-STEM.

FIG. 21 shows an exemplary method.

### DETAILED DESCRIPTION OF THE DRAWINGS

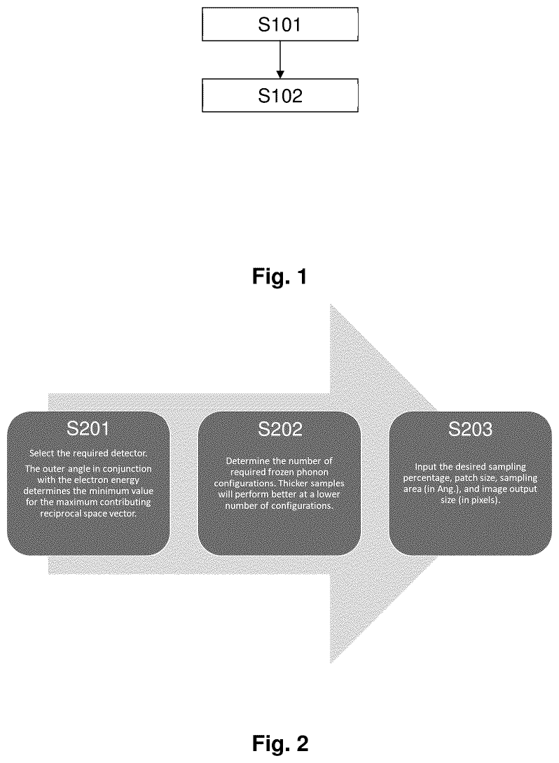

FIG. 1 schematically depicts a method according to an exemplary embodiment. The method is of simulating an electron microscopy image of a sample. The method is implemented by a computer comprising a processor and a memory.

At S101, the method comprises obtaining parameters of the electron microscopy, attributes of the sample and respective thresholds of one or more target properties of the simulated electron microscopy image.

At S102, the method comprises computing the simulated electron microscopy image of size [M×N] pixels of the sample using the obtained parameters of the electron microscopy and the obtained attributes of the sample, according to the obtained respective thresholds of the one or more target properties of the simulated electron microscopy image.

The method may include any of the steps described with respect to the first aspect.

FIG. 2 schematically depicts a method of a sub-sampled simulation with three different (modular) processes according to an exemplary embodiment. Particularly, FIG. 2 schematically depicts an exemplary embodiment of step S102 of FIG. 1, in more detail.

At S201, the required electron microscopy detector is selected. The outer angle in conjunction with the electron energy determines the minimum value for the maximum reciprocal space vector.

At S202, the number of required frozen phonon configurations is determined. Thicker samples will perform better at a lower number of configurations.

At S203, the desired sampling percentage, patch size, sampling area (in Ångströms) and image output size (in pixels) are input.

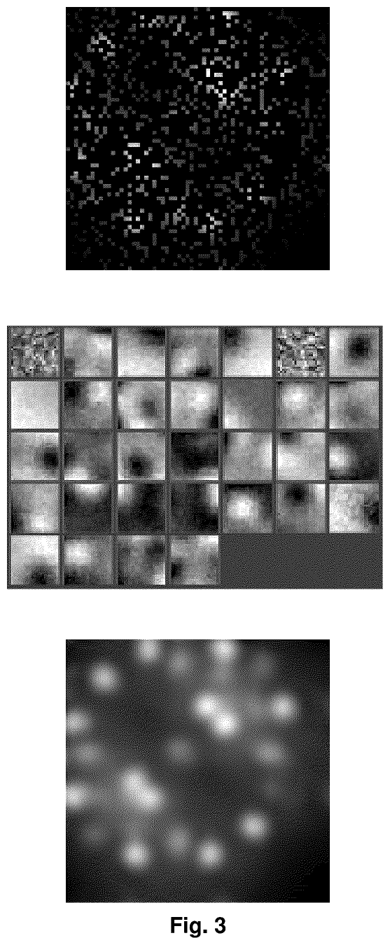

FIG. 3 shows reconstruction of a sub-sampled simulation where only the space is compressed (neither the number of FPCs or maximum reciprocal space vector are optimised).

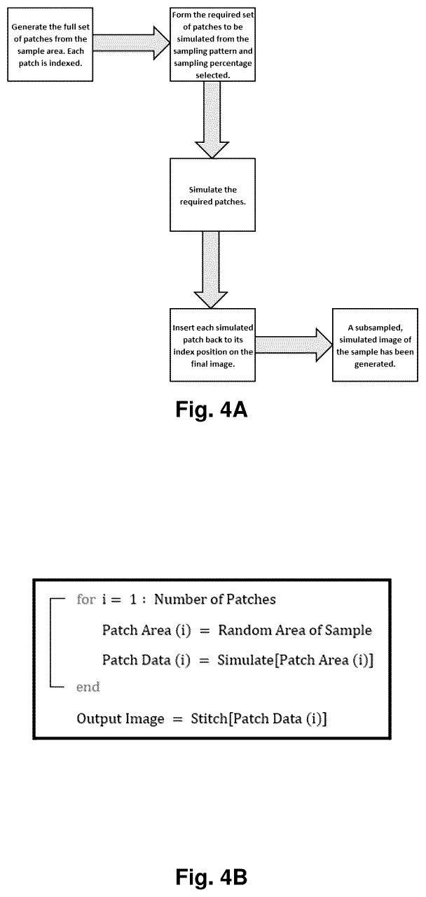

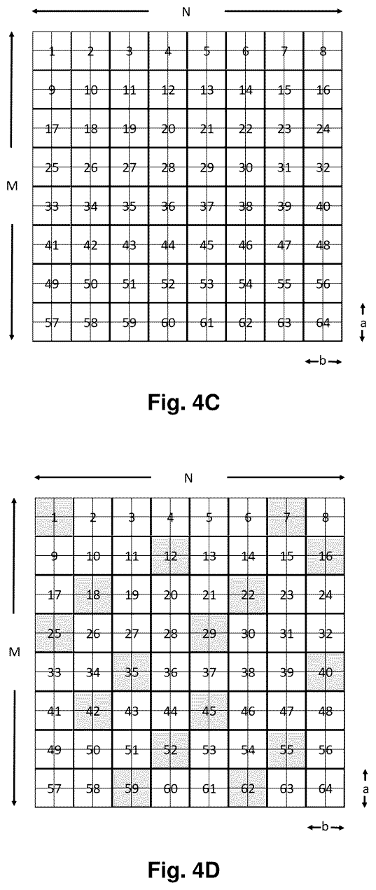

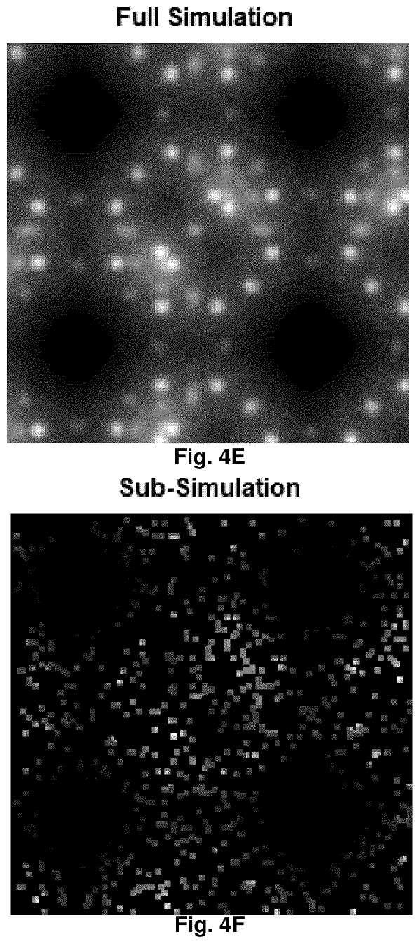

FIG. 4A shows a workflow to form a sub-sampled, simulated image; FIG. 4B is Pseudo Code for Random Patch Acquisition. FIG. 4C schematically depicts an image of size [M×N] pixels broken down into a set of patches size [a×b]. Each patch is then indexed and creates a vector of patches which can be individually simulated depending on the desired scan pattern and sampling percentage. FIG. 4D schematically depicts the simulated patches restored back into their respective index position, and those which are not simulated are set to a value of zero.

FIG. 4E is an example of a Full Simulation. FIG. 4F is the Sub-sampled Simulated Counterpart of FIG. 4E.

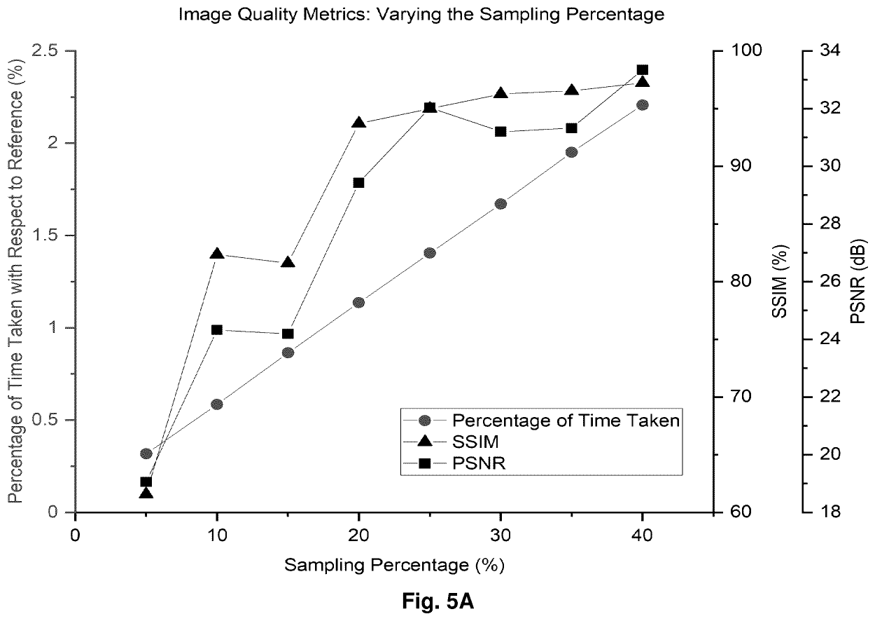

FIG. 5A shows the effect of sampling percentage a reconstruction quality. Particularly, the percentage of time taken, relative to full simulation, increases linearly as a function of sampling percentage (%) in a range from 5% to 40%, from about 0.25% to 2.25% i.e. between about a ×400 and a ×40 improvement in runtime. However, the SSIM and PSNR, calculated with reference to the full simulation image, increase rapidly from about 65% for a 5% sampling percentage to about 95% and 90% respectively for a 20% sampling percentage. Increasing the sampling percentage to 40% further improves the SSIM and PSNR to each better than 95% but approximately doubles the runtime. Hence, a sampling percentage of 20% balances quality and runtime, for this example.

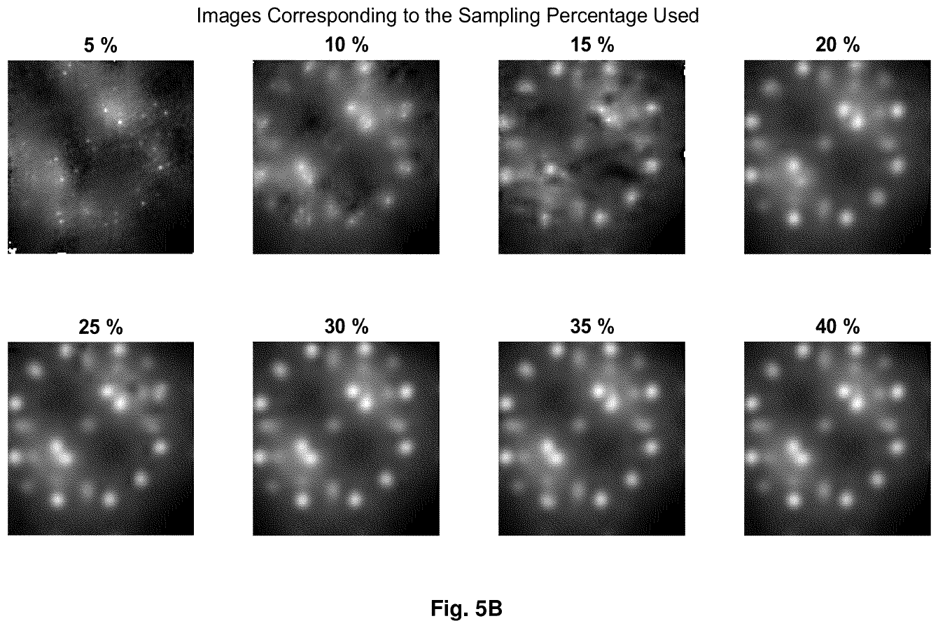

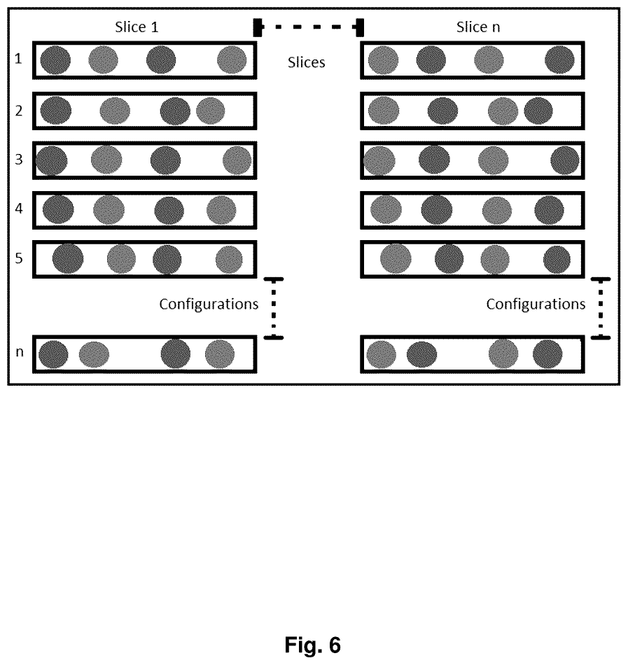

FIG. 6 schematically depicts frozen phonon configurations. In more detail, FIG. 6 is a visual representation of how the frozen phonon approximation is used to estimate the thermal-diffuse scattering. For each slice of the multislice, the atomic displacement is randomly assigned for n-configurations. The intensity is calculated for each configuration, and then averaged to determine the intensity of the final image.

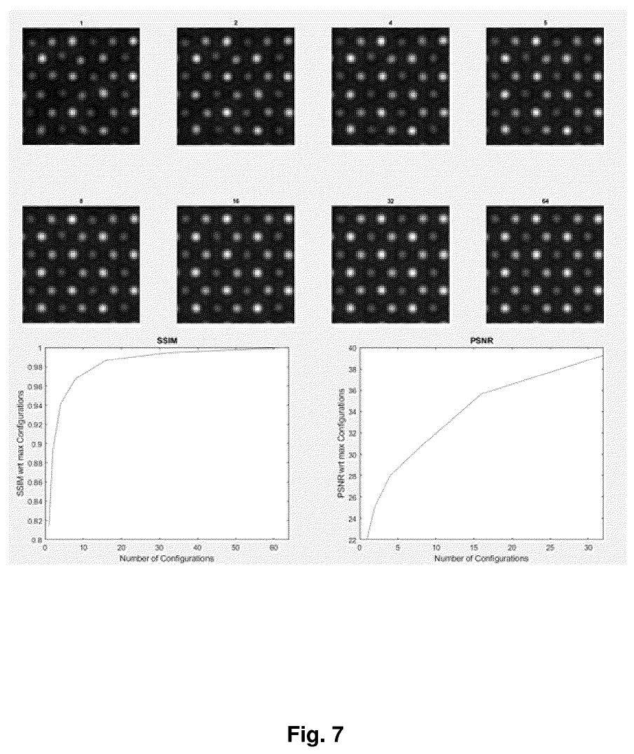

FIG. 7 shows how varying the number of frozen phonon configurations (the number above each image) effects the output simulation. Each SSIM and PSNR value is taken with respect to the maximum number used (in this case 64).

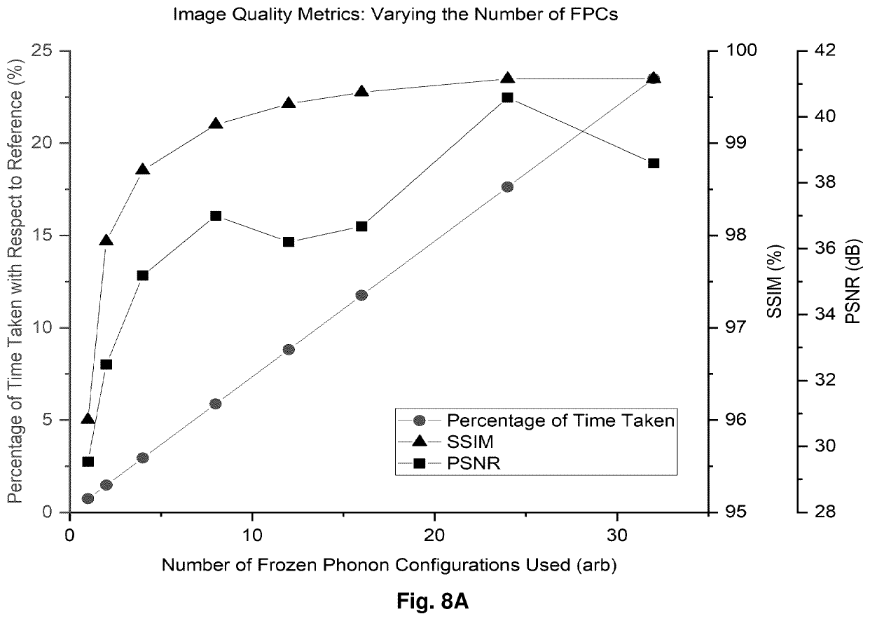

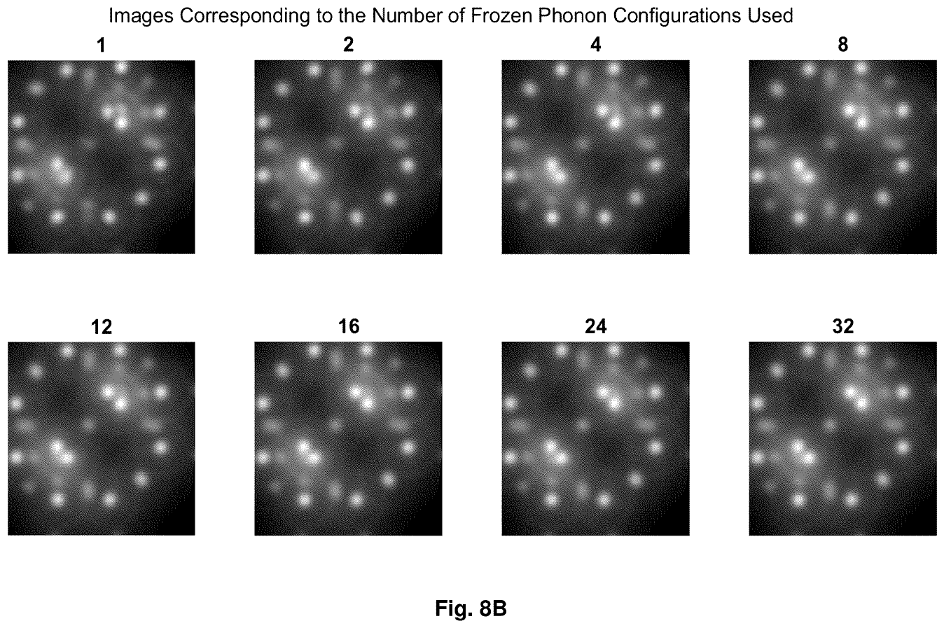

FIG. 8A shows the result of increasing the number of frozen phonon configurations upon run-time and image quality metrics. PSNR stops since its value is infinite when the reference image is the same as the input. Particularly, the percentage of time taken, relative to full simulation, increases linearly as a function of the number of frozen phonon configurations in a range from 1 to 32 from about 1% to 23% i.e. between about a ×100 and a ×4 improvement in runtime. However, the SSIM, calculated with reference to the full simulation image, increases rapidly from about 96% for 1 frozen phonon configuration to about 99.5% for 12 frozen phonon configurations. The PSNR increases more slowly than the SSIM, from about 95.5% to about 98% over the same range. Increasing the number of frozen phonon configurations to 32 further improves the SSIM and PSNR to better than 99.5% and better than 98.5% respectively but approximately trebles the runtime. Hence, a number of frozen phonon configurations in a range from 1 to 12 balances quality and runtime, for this example.

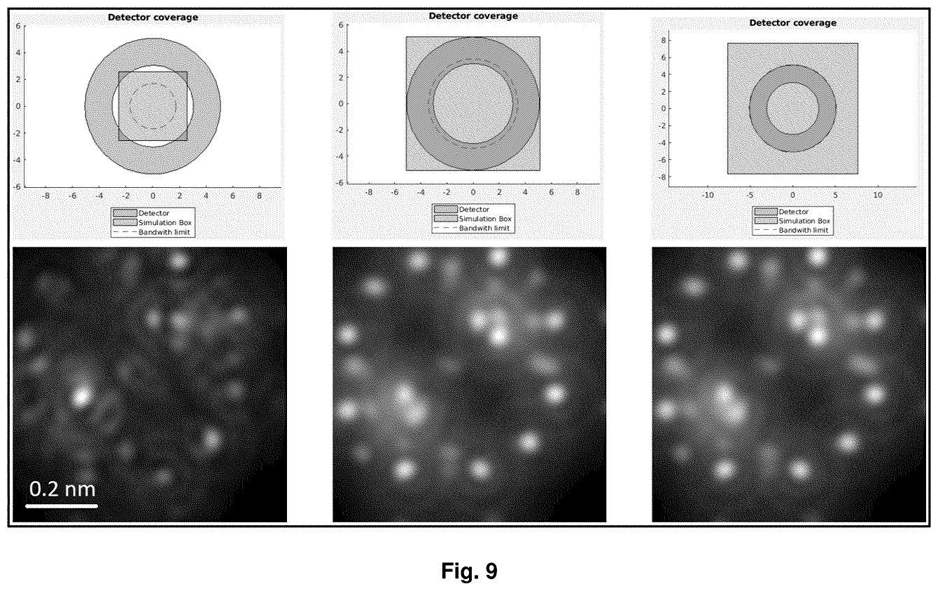

FIG. 9 is a demonstration of how the increase in simulation box sampling has diminishing returns on the output image. Beyond the length of the simulation box being equal to the outer diameter of the detector (upper right), the simulations are functionally identical (lower middle, lower right).

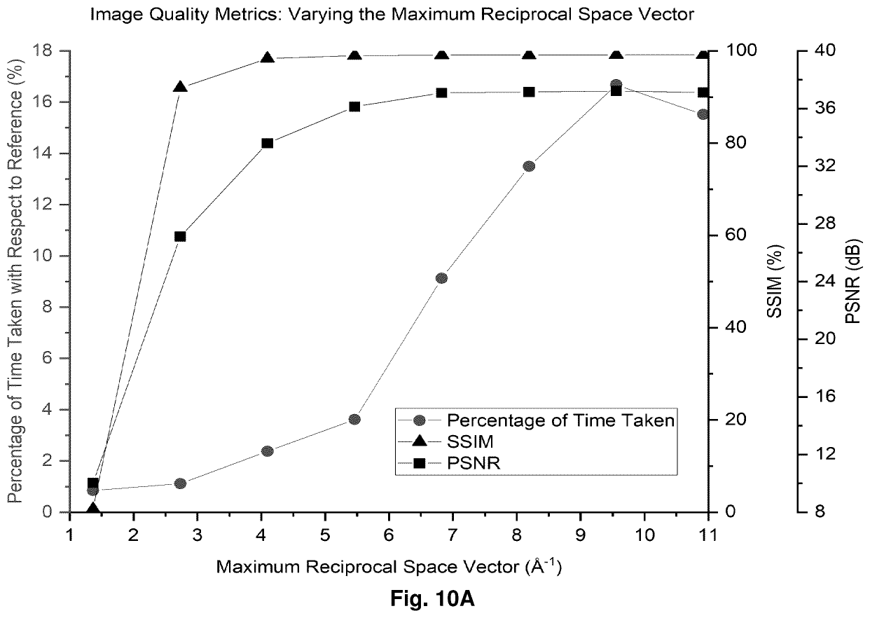

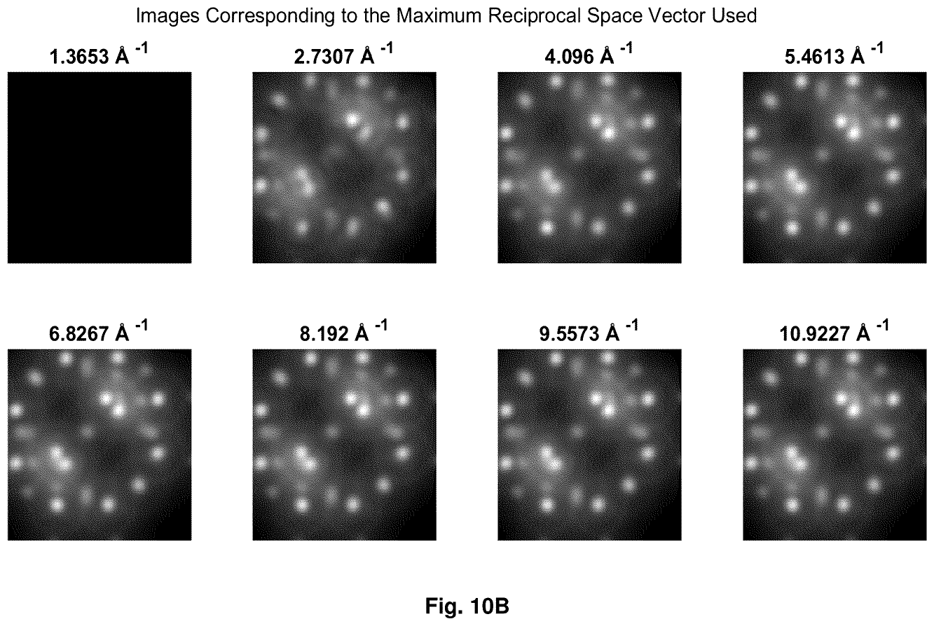

FIG. 10A is a demonstration of how the increase the maximum reciprocal space vector used has diminishing returns on the output image. Beyond the length of the simulation box being equal to the outer diameter of the detector, the simulations are functionally identical Particularly, the percentage of time taken, relative to full simulation, increases as a function of the maximum reciprocal space vector, in a range from 1 Å⁻¹ to 11 Å⁻¹, from about 1% to 15% i.e. between about a ×100 and a ×6 improvement in runtime. However, the SSIM, calculated with reference to the full simulation image, increases rapidly from about 5% for a maximum reciprocal space vector of about 1 Å⁻¹ to about 90% for a maximum reciprocal space vector of about 2.5 Å-1. The PSNR increases more slowly than the SSIM, from about 5% to about 60% over the same range. Increasing the maximum reciprocal space vector to about 11 Å⁻¹ further improves the SSIM and PSNR to better than 99.5% and better than 90% respectively but increases the runtime by a factor of approximately 15. Hence, a maximum reciprocal space vector in a range from 2 Å⁻¹ to 4 Å⁻¹ balances quality and runtime, for this example. The example used is for the specifications of the sample and the microscope in section regarding microscope and sample specification. This value for FPC, and KMAX will vary depending on specification but k max is automatically calculated by equation in section Optimising maximum contributing reciprocal space vector.

All three methods were used in conjunction to simulate a zeolite structure (ZK-5). The output simulation has a size of 128×128 pixels (8 Å×8 Å) and was simulated with a sampling percentage of 25% over a random sampling pattern. The number of frozen phonon configurations per slice was 4 and the simulation box was limited to the size of the detector with a maximum reciprocal space vector of 5.12 Å⁻¹.

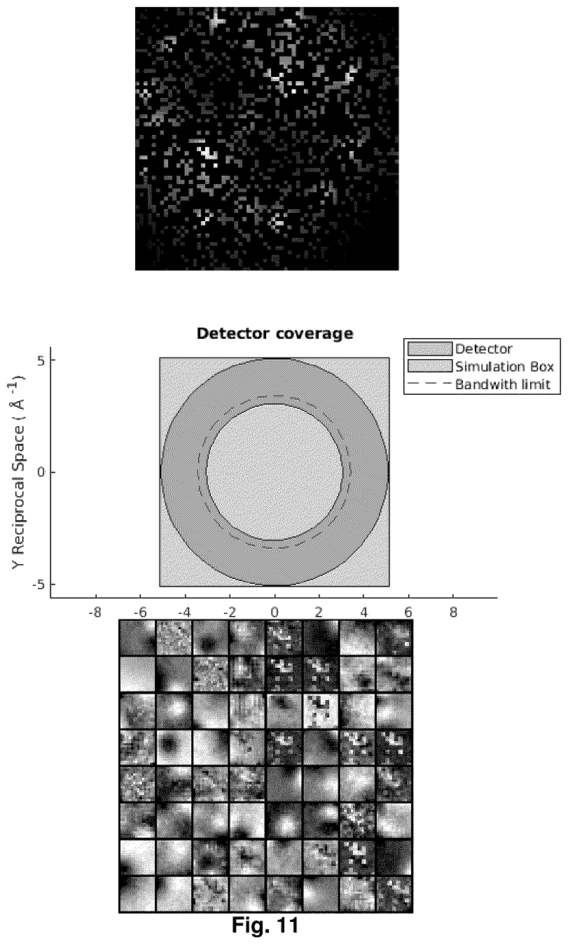

FIG. 11 shows a 25% sub-sampled simulation (top) of ZK-5, the simulation box with an optimised maximum reciprocal space vector (middle), and the dictionary generated by BPFA-EM from the sub-sampled data (bottom). The number of frozen phonon configurations used is 4.

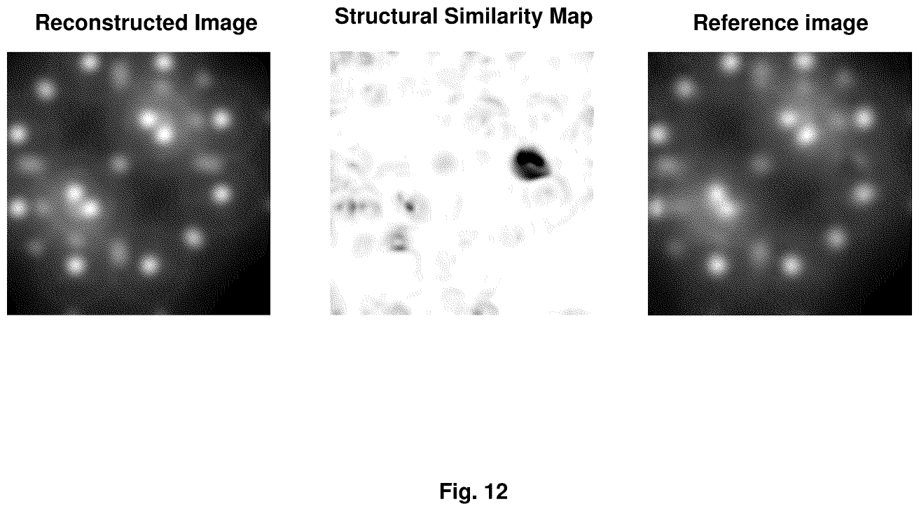

FIG. 12 shows a Compressed Simulation (left) and Full Sampled Simulation (right) of ZK-5. In more detail, FIG. 12 shows an example of a simulated image of ZK-5 zeolite (left). The simulation was performed using MULTEM through Matlab on a remote server with a GPU cluster. The simulated image is a HAADF STEM simulation with an accelerating voltage of 300 kV on a detector with inner and outer angles of 60 mrad and 100 mrad respectively. The simulation used 32 frozen phonon configurations, and a maximum reciprocal space vector of 10.923 Å⁻¹. The sampling area was [X Y Z]_start→[X Y Z]_end; [20 20 0]→[28 28 93.75] Å mapped onto a 128×128 pixel area, such that we have 0.0625 Å/Pixel. The simulated image size has been rescaled from 128×128 to 256×256 for illustrative purposes only. Generally, simulations described herein were performed similarly, mutatis mutandis, unless noted otherwise. In the similarity map, the dark features correspond to variations between the reference and reconstruction. In a perfect reconstruction (i.e. SSIM is 100%), the similarity map would be completely white.

The resulting compressed simulation has a structural similarity of 94.8% and a peak signal-to-noise ratio value of 30.79 dB. The run-time was approximately 87× faster than the fully sampled simulation, and reconstruction time was a matter of seconds, with most of this time spent forming the dictionary.

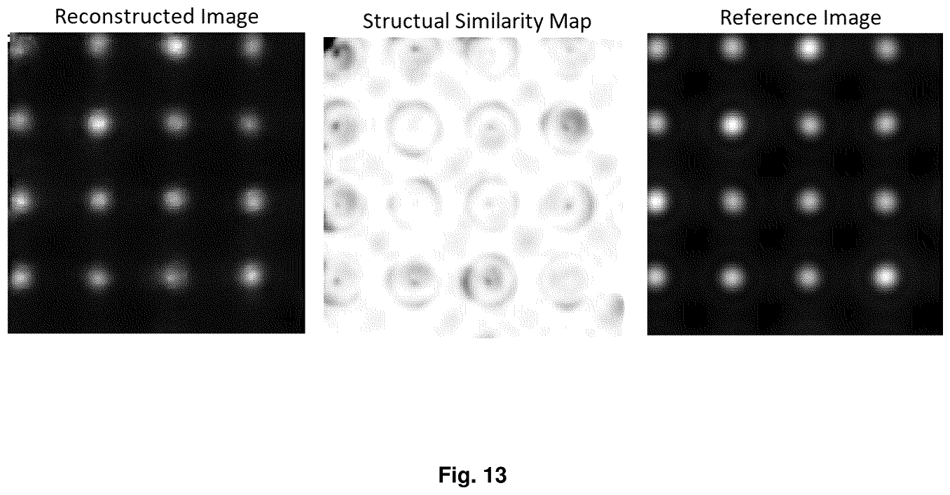

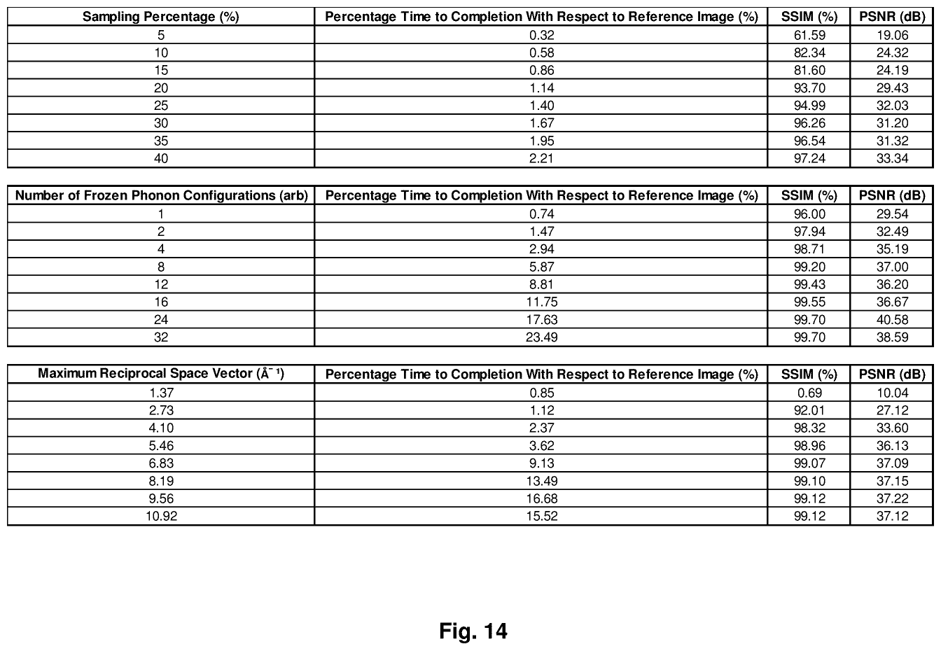

FIG. 13 is an example of LMO Sample with reduced k-vector sampling, reduced FPCs and 20% subsampling. In combination and using image inpainting, these processes described herein provide a significant reduction in the run-time of a simulation with functionally identical results. This is shown in FIG. 13 of a lithium manganese oxide sample, where the run-time is decreased by approximately 90%, with over 93% similarity to the full simulation. The inventors also recognise that any method that directly reduces the amount of information acquired during a simulation to be counted as a subsampling technique.

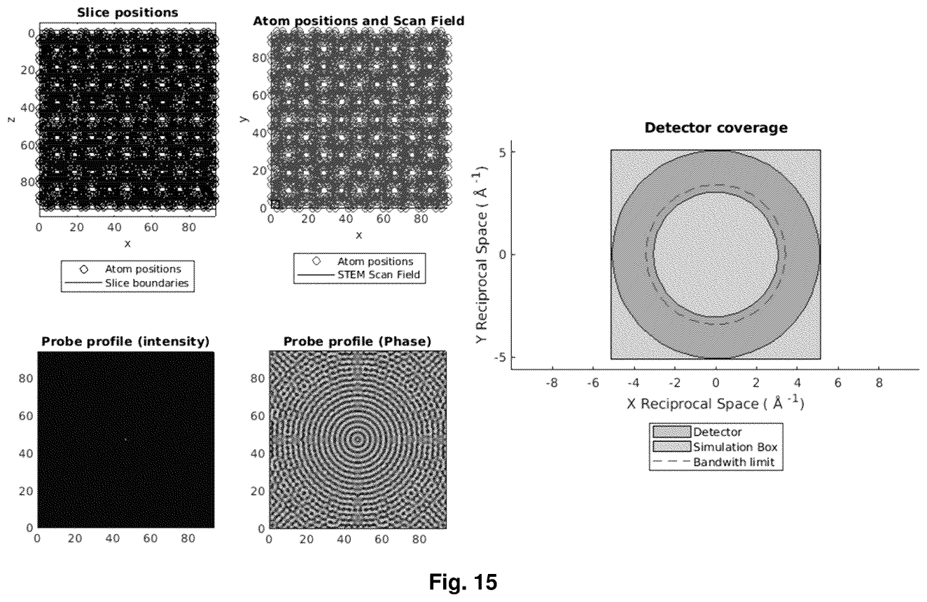

FIG. 15 shows details of the sub-sampled simulation of ZK-5, using MULTEM, with reference to Table 2 and Table 3.

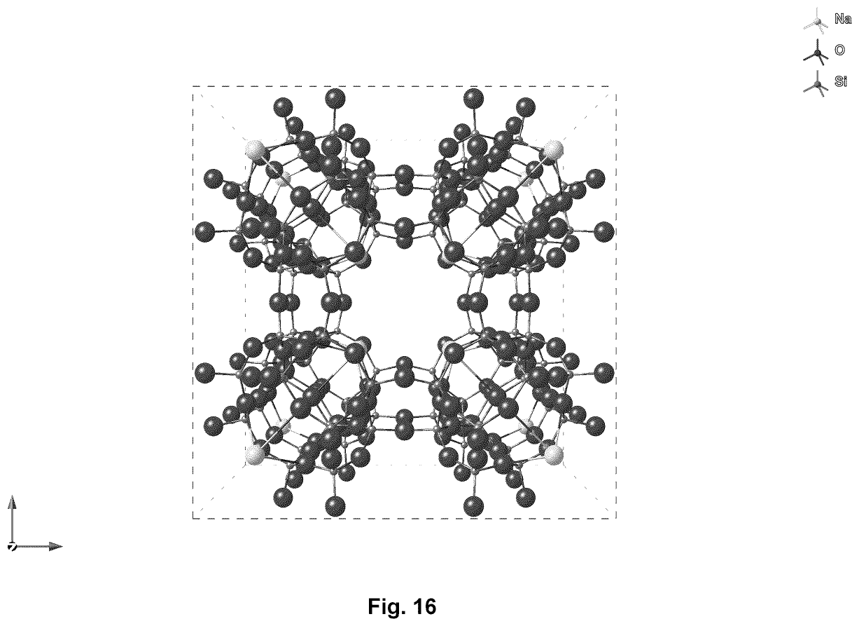

Table 2 summarises attributes of the ZK-5 sample for the sub-sampled simulation of ZK-5. FIG. 16 shows a structure image of a unit cell of ZK-5.

TABLE 2
Attributes of the ZK-5 sample.

| Structure Type | Crystal | |
|---|---|---|
| Chemical Formula | Na Si₆ O₁₂ | |
| Z | 16 | |
| Space Group | I m 3̅ m | |
| Crystal System | Cubic | |
| a | 18.7500 | Å |
| Cell Volume | 6591.797 | Å³ |
| Asymmetric Unit | 6 | sites |
| Unit Cell | 304 | sites/unit cell |
| Density | 1.5459 | g/cm³ |

| | |
|---|---|
| Visible Sites | 328 |
| Thickness | XXX |

Table 3 summarises parameters of the electron microscopy of the ZK-5 sample (imaged in xy plane), for a HAADF STEM simulation with an accelerating voltage of 300 kV on a detector with inner and outer angles of 60 mrad and 100 mrad respectively.

TABLE 3
Parameters of the electron microscopy of the ZK-5 sample.

CONDENSER LENS
cond_lens_m(1,1) double = 0.00; % Vortex momentum
cond_lens_c_10(1,1) double = 14.0312; % [C1] Defocus (Angstrom)
cond_lens_c_12(1,1) double = 0.00; % [A1] 2-fold astigmatism (Angstrom)
cond_lens_phi_12(1,1) double = 0.00; % [phi_A1] Azimuthal angle of 2-fold astigmatism
(Angstrom)
cond_lens_c_21(1,1) double = 0.00; % [B2] Axial coma (Angstrom)
cond_lens_phi_21(1,1) double = 0.00; % [phi_B2] Azimuthal angle of axial coma (Angstrom)
cond_lens_c_23(1,1) double = 0.00; % [A2] 3-fold astigmatism (Angstrom)
cond_lens_phi_23(1,1) double = 0.00; % [phi_A2] Azimuthal angle of 3-fold astigmatism
(Angstrom)
cond_lens_c_30(1,1) double = 1e−3; % [C3] 3rd order spherical aberration (mm)
cond_lens_c_32(1,1) double = 0.00; % [S3] Axial star aberration (Angstrom)
cond_lens_phi_32(1,1) double = 0.00; % [phi_S3] Azimuthal angle of axial star aberration
(Angstrom)
cond_lens_c_34(1,1) double = 0.00; % [A3] 4-fold astigmatism (Angstrom)
cond_lens_phi_34(1,1) double = 0.00; % [phi_A3] Azimuthal angle of 4-fold astigmatism
(Angstrom)
cond_lens_c_41(1,1) double = 0.00; % [B4] 4th order axial coma (Angstrom)
cond_lens_phi_41(1,1) double = 0.00; % [phi_B4] Azimuthal angle of 4th order axial coma
(Angstrom)
cond_lens_c_43(1,1) double = 0.00; % [D4] 3-lobe aberration (Angstrom)
cond_lens_phi_43(1,1) double = 0.00; % [phi_D4] Azimuthal angle of 3-lobe aberration
(Angstrom)
cond_lens_c_45(1,1) double = 0.00; % [A4] 5-fold astigmatism (Angstrom)
cond_lens_phi_45(1,1) double = 0.00; % [phi_A4] Azimuthal angle of 5-fold astigmatism
(Angstrom)
cond_lens_c_50(1,1) double = 0.00; % [C5] 5th order spherical aberration (mm)
cond_lens_c_52(1,1) double = 0.00; % [S5] 5th order axial star aberration (Angstrom)
cond_lens_phi_52(1,1) double = 0.00; % [phi_S5] Azimuthal angle of 5th order axial star
aberration (Angstrom)
cond_lens_c_54(1,1) double = 0.00; % [R5] 5th order rosette aberration (Angstrom)
cond_lens_phi_54(1,1) double = 0.00; % [phi_R5] Azimuthal angle of 5th order rosette
aberration (Angstrom)
cond_lens_c_56(1,1) double = 0.00; % [A5] 6-fold astigmatism (Angstrom)
cond_lens_phi_56(1,1) double = 0.00; % [phi_A5] Azimuthal angle of 6-fold astigmatism
(Angstrom)
cond_lens_inner_aper_ang(1,1) double = 7.00; % Inner aperture (mrad)
cond_lens_outer_aper_ang(1,1) double = 21.0; % Outer aperture (mrad)
source spread function
cond_lens_si_a(1,1) double = 1.0% Height proportion of a normalized Gaussian [0, 1]
cond_lens_si_sigma(1,1) double = 0.0072; % standard deviation: For parallel
ilumination(Angstrom\hat{ }−1); otherwise (Angstrom)
cond_lens_si_beta(1,1) double = 0.2; % Standard deviation of the source spread function for
the Exponential component: For parallel ilumination( [symbol] \hat{ }−1); otherwise ( [symbol] )
cond_lens_si_rad_npts(1,1) uint64 = 4; % # of integration points. It will be only used if
illumination_model=4
cond_lens_si_azm_npts(1,1) uint64 = 4; % # of radial integration points. It will be only used if
illumination_model=4
defocus spread function
cond_lens_ti_a(1,1) double = 1.0; % Height proportion of a normalized Gaussian [0, 1]
cond_lens_ti_sigma(1,1) double = 32.0; % standard deviation (Angstrom)
cond_lens_ti_beta(1,1) double = 0.0; % Standard deviation of the defocus spread for the
Exponential component
cond_lens_ti_npts(1,1) uint64 = 10; % # of integration points. It will be only used if
illumination_model=4
zero defocus reference

| | |
|---|---|
| cond_lens_zero_defocus_type(1,1) | uint64 |

{mustBeLessThanOrEqual(cond_lens_zero_defocus_type,4), mustBePositive} = 1; %
eZDT_First = 1, eZDT_User_Define = 4
cond_lens_zero_defocus_plane(1,1) double = 0.00; % It will be only used if
cond_lens_zero_defocus_type = eZDT_User_Define
OBJECTIVE LENS
obj_lens_m(1,1) double = 0; % Vortex momentum
obj_lens_c_10(1,1) double = 14.0312; % [C1] Defocus (Angstrom)
obj_lens_c_12(1,1) double = 0.00; % [A1] 2-fold astigmatism (Angstrom)
obj_lens_phi_12(1,1) double = 0.00; % [phi_A1] Azimuthal angle of 2-fold astigmatism
(Angstrom)
obj_lens_c_21(1,1) double = 0.00; % [B2] Axial coma (Angstrom)
obj_lens_phi_21(1,1) double = 0.00; % [phi_B2] Azimuthal angle of axial coma (Angstrom)
obj_lens_c_23(1,1) double = 0.00; % [A2] 3-fold astigmatism (Angstrom)
obj_lens_phi_23(1,1) double = 0.00; % [phi_A2] Azimuthal angle of 3-fold astigmatism
(Angstrom)
obj_lens_c_30(1,1) double = 1e−03; % [C3] 3rd order spherical aberration (mm)
obj_lens_c_32(1,1) double = 0.00; % [S3] Axial star aberration (Angstrom)
obj_lens_phi_32(1,1) double = 0.00; % [phi_S3] Azimuthal angle of axial star aberration
(Angstrom)
obj_lens_c_34(1,1) double = 0.00; % [A3] 4-fold astigmatism (Angstrom)
obj_lens_phi_34(1,1) double = 0.00; % [phi_A3] Azimuthal angle of 4-fold astigmatism
(Angstrom)
obj_lens_c_41(1,1) double = 0.00; % [B4] 4th order axial coma (Angstrom)
obj_lens_phi_41(1,1) double = 0.00; % [phi_B4] Azimuthal angle of 4th order axial coma
(Angstrom)
obj_lens_c_43(1,1) double = 0.00; % [D4] 3-lobe aberration (Angstrom)
obj_lens_phi_43(1,1) double = 0.00; % [phi_D4] Azimuthal angle of 3-lobe aberration
(Angstrom)
obj_lens_c_45(1,1) double = 0.00; % [A4] 5-fold astigmatism (Angstrom)
obj_lens_phi_45(1,1) double = 0.00; % [phi_A4] Azimuthal angle of 5-fold astigmatism
(Angstrom)
obj_lens_c_50(1,1) double = 0.00; % [C5] 5th order spherical aberration (mm)
obj_lens_c_52(1,1) double = 0.00; % [S5] 5th order axial star aberration (Angstrom)
obj_lens_phi_52(1,1) double = 0.00; % [phi_S5] Azimuthal angle of 5th order axial star
aberration (Angstrom)
obj_lens_c_54(1,1) double = 0.00; % [R5] 5th order rosette aberration (Angstrom)
obj_lens_phi_54(1,1) double = 0.00; % [phi_R5] Azimuthal angle of 5th order rosette
aberration (Angstrom)
obj_lens_c_56(1,1) double = 0.00; % [A5] 6-fold astigmatism (Angstrom)
obj_lens_phi_56(1,1) double = 0.00; % [phi_A5] Azimuthal angle of 6-fold astigmatism
(Angstrom)
obj_lens_inner_aper_ang(1,1) double = 0.00; % Inner aperture (mrad)
obj_lens_outer_aper_ang(1,1) double = 24.0; % Outer aperture (mrad)
defocus spread function
obj_lens_ti_sigma(1,1) double = 32; % standard deviation (Angstrom)
obj_lens_ti_npts(1,1) uint64 = 10; % # of integration points. It will be only used if
illumination_model=4
zero defocus reference

| | |
|---|---|
| obj_lens_zero_defocus_type(1,1) | uint64 |

{mustBeLessThanOrEqual(obj_lens_zero_defocus_type,4), mustBePositive} = 1; %
eZDT_First = 1, eZDT_Middle = 2, eZDT_Last = 3, eZDT_User_Define = 4
obj_lens_zero_defocus_plane(1,1) double = 0.00;

### Targeted Sampling Strategies Towards Real Time STEM Simulation

The inventors have shown that the run-time of STEM simulations can be significantly reduced with functionally identical results through signal compression methods. The spatial acquisition, reciprocal space acquisition, and number of frozen phonon configurations can be reduced and then reconstructed to form the full image using an inpainting algorithm. Herein is described and demonstrated a new method that can significantly improve the efficiency compared to previous work through a targeted sampling strategy, along with a new approach to independently sub-sample each frozen phonon layer. The results show that it is possible to achieve 92% similarity with only 3% spatial sampling, and the potential to reduce run-times by factors of up to 400× without significant loss of simulation quality.

One of the initial steps to improving the efficiency of compressed simulations was to consider the sampling strategy used to acquire the spatial signal. According to compressive sensing (CS) theory, purely random sampling is the best which has been used in previous work. However, given that high resolution STEM simulations contain a significant amount of ‘vacuum’ space, the number of pixels sampled which contained no signal was disproportionate. This meant that too much time was spent sampling on vacuum space relative to more important features, such as atoms.

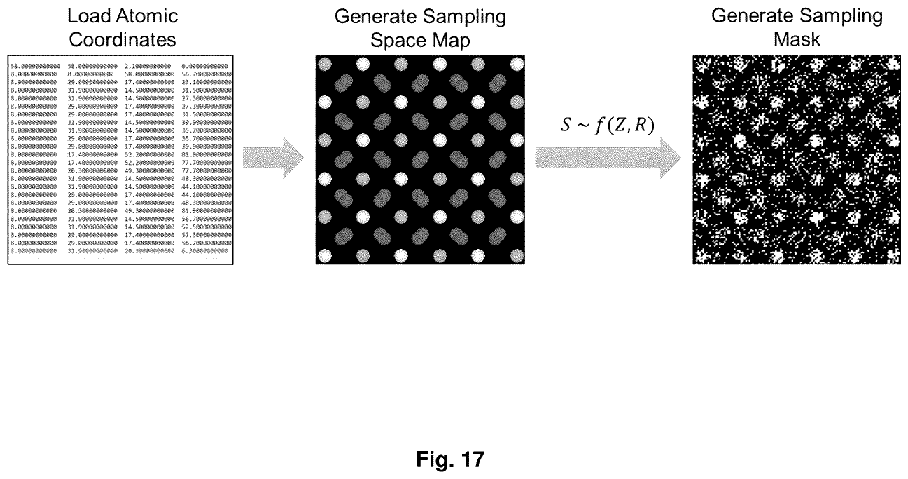

The luxury of STEM simulations is that one must inform the software of atom locations, which for MULTEM is a file containing atomic coordinates, atomic number, charge and so on. Therefore, it is proposed that this file could also be used as a method to form a targeted sampling mask which prioritises sampling on atoms, as opposed to a purely random approach. However, the sampling is not purely targeted, but also includes some bias, R, which allows any location to be sampled with some likelihood, S. This essentially makes the mask a layer of purely random sampling (required by CS theory), and purely targeted based on the atomic number, Z, to optimise the sampling strategy. See FIG. 17.

The second step towards improving the efficiency of STEM simulation is to optimise how the frozen phonon model can be adapted through a targeted sampling method. The frozen phonon model is used to account for thermal diffuse scattering within the sample, and essentially takes a snapshot of the sample at some given time where the atom locations are slightly displaced from their equilibrium position depending on the Debye Waller factor (DWF) of the atom. Each snapshot of atom positions is known as a frozen phonon configuration (FPC) and the more configurations considered, generally the more accurate the simulation is, given the final simulation is the average of all simulations over varying configurations.

In practice, it was shown in previous work that beyond some number of configurations (thickness dependent), the improvement in simulation quality diminished, however the run-time scaled linearly. Therefore, for the purpose of speeding up simulations, it was better to limit the number of configurations at the point where the quality improvement begins to diminish.

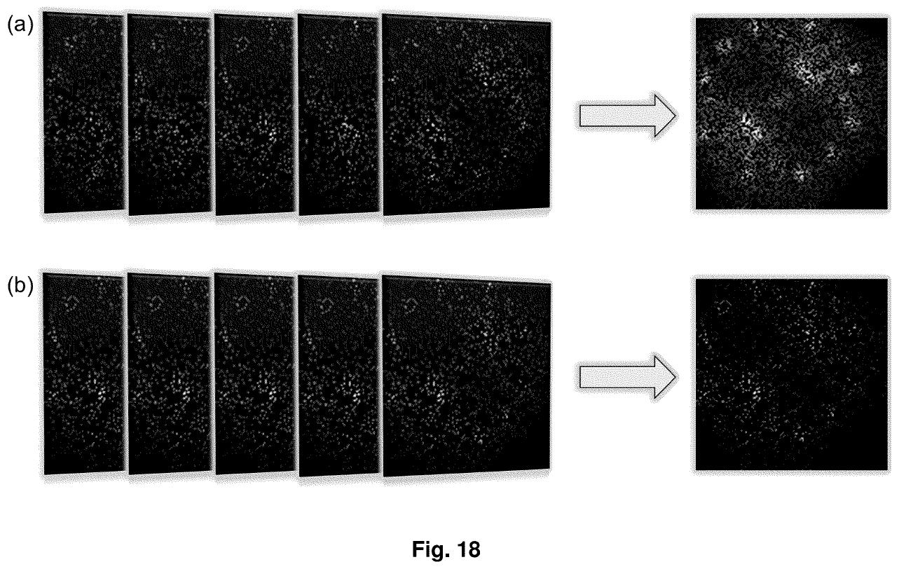

However, consider sampling at a location where there is no atom. Here the number of configurations used is relatively insignificant to the intensity of the pixel at that location, and therefore to continue sampling this position would be time inefficient. It would be better to sample on atoms more frequently where the frozen phonon approximation matters more. This can be achieved by using a different targeted mask for each FPC rather than using the same mask each time. This will also increase the net sampling of the final simulation as the pixel values are averaged in the final step, as well as reducing the total sampling ratio required for each independent configuration. See FIG. 18.

These two methods, when used in conjunction, can yield a final simulation that still respects the frozen phonon approximation and its importance, but also reduces the overall sampling so that run-time decreases, and the net sampling increases if the parameters are sufficient.

The spatially subsampled simulations are reconstructed through an inpainting algorithm. The inpainting algorithm consists of two key parts-a (blind) dictionary learning algorithm, followed by a sparse coding algorithm. The image recovery problem is turned into a Bayesian dictionary learning problem based on the Beta Process Factor Analysis (BPFA) developed in Paisley 2009 and Zhou 2009. Readers are referred to Nicholls 2022 for more details on the algorithm which are omitted here.

To test these methods and to find limitations, compressed simulations of bulk strontium titanate were performed. The reference, fully sampled simulation was performed semi-compressively using methods from previous work, as the maximum reciprocal space vector was limited to the maximum angle of the HAADF detector at 100 mrad. Furthermore, the number of FPCs used was 10. The simulation was not spatially subsampled either. In all cases, the simulations were performed using MULTEM through MATLAB on a remote server equipped with an Intel Xeon Gold 6128 CPU @ 3.40 GHz, and one NVIDIA Telsa V100 GPU running CUDA 11.2. All simulations are performed with the same microscope and detector parameters. The simulated images are HAADF STEM simulations with an accelerating voltage of 300 kV on a detector with inner and outer angles of 60 mrad and 100 mrad respectively. All BPFA-EM reconstructions were performed with 128 dictionary elements, with a patch size of [20×20] pixels.

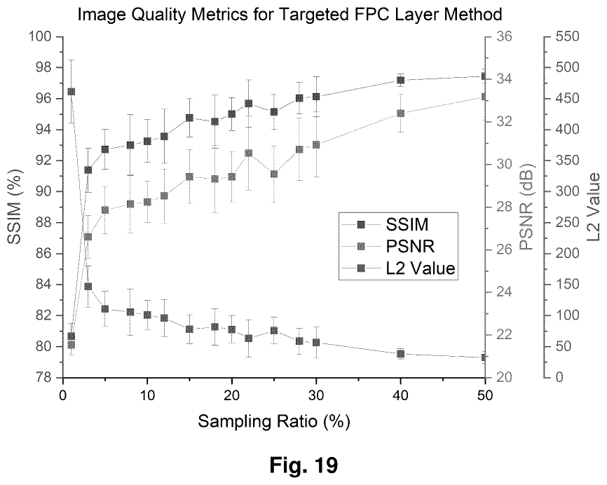

The method was tested for sampling ratios ranging from 1% to 50% per layer. Furthermore, for each sampling ratio, the simulation was performed 10 times to get an average image quality metric following each reconstruction using BPFA-EM. See FIG. 19.

As the results show, it is possible to significantly reduce the sampling ratio per layer and still achieve functionally identical results by combining a targeted sampling strategy with a varying mask for each FPC. Given that the run-time scales linearly with the sampling ratio, even at a sampling ratio of 3%, then the theoretical run-time improvement based on the previous method has improved from 87× faster, to upwards of 400× faster.

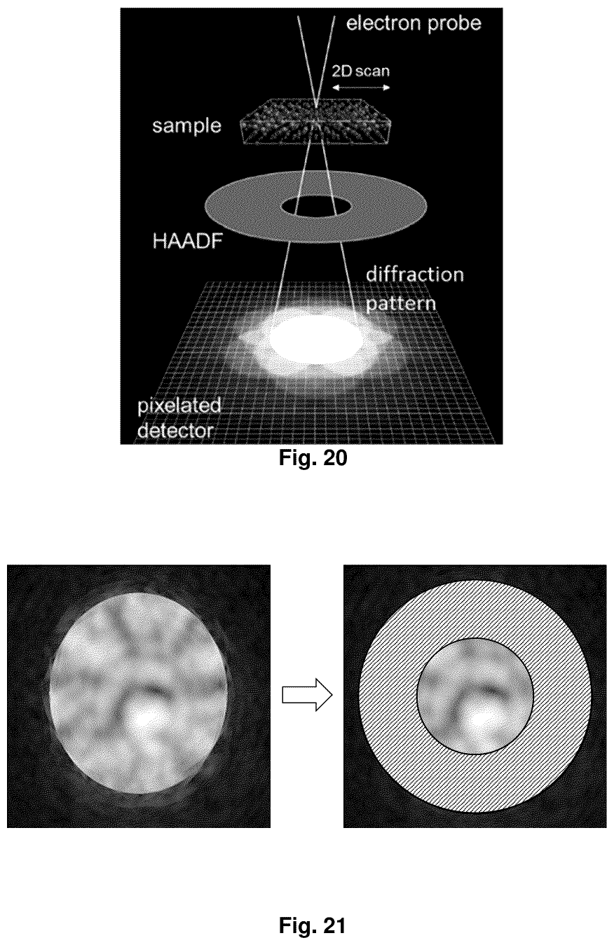

FIG. 20 schematically depicts 4D-STEM. If the number of probe positions covers a real space of [x, y], and the size of each convergent beam electron diffraction pattern (CBED) covers a reciprocal space of [kₓ, k_{y}], then the 4D-STEM data set has dimension [x, y, kₓ, k_{y}].

FIG. 21 shows an exemplary method.

A virtual detector is equivalent to a radial detector in a STEM. The virtual detector is the integration of binary signals in taken from the CBED pattern on the pixelated detector.

FIG. 21 shows applying a virtual detector to CBED (left to right). The intensity on the diagonal pattern filled ring is integrated to have an equivalent to a HAADF.

Virtual detectors may be applied to compressed simulations by spatially sub-sampling the simulations and collecting a finite number of CBEDs that correlate to certain probe positions. Then, a sub-sampled image may be formed which corresponds to a certain scattering range using a virtual detector. This allows for all standard STEM image types to be formed from one data set. Furthermore, this may be applied to the simulation of ptychography and other 4D-STEM methods.

The novelty of this is the method of subsampling probe positions to form a subsampled 4D-STEM data set. If the number of probe positions covers a real space of [x, y], and the size of each CBED covers a reciprocal space of [kₓ, k_{y}], and we have a sampling ratio of S, then the total data set is reduced by factor of 1/S. This makes the simulation faster, but also reduces the data storage required, as well as providing a useful tool for real 4D-STEM acquisition.

Although a preferred embodiment has been shown and described, it will be appreciated by those skilled in the art that various changes and modifications might be made without departing from the scope of the invention, as defined in the appended claims and as described above.

### REFERENCES

[1] Pennycook S J, Nellist P D. Scanning transmission electron microscopy: imaging and analysis. Springer Science & Business Media; 2011.
[2] Lobato I, Van Dyck D. MULTEM: A new multislice program to perform accurate and fast electron diffraction and imaging simulations using Graphics Processing Units with CUDA. Ultramicroscopy. 2015; 156:9-17.
[3] Paisley, J. and Carin, L., 2009 June. Nonparametric factor analysis with beta process priors. In Proceedings of the 26th annual international conference on machine learning (pp. 777-784).
[4] Zhou, M., Paisley, J. and Carin, L., 2009 December. Nonparametric learning of dictionaries for sparse representation of sensor signals. In 2009 3rd IEEE International Workshop on Computational Advances in Multi-Sensor Adaptive Processing (CAMSAP) (pp. 237-240). IEEE.
[5] Nicholls, D., Wells, J., Stevens, A., Zheng, Y., Castagna, J. and Browning, N. D., 2022. Sub-sampled imaging for stem: Maximising image speed, resolution and precision through reconstruction parameter refinement. Ultramicroscopy, 233, p.113451.

### Notes

At least some of the example embodiments described herein may be constructed, partially or wholly, using dedicated special-purpose hardware. Terms such as ‘component’, ‘module’ or ‘unit’ used herein may include, but are not limited to, a hardware device, such as circuitry in the form of discrete or integrated components, a Field Programmable Gate Array (FPGA) or Application Specific Integrated Circuit (ASIC), which performs certain tasks or provides the associated functionality. In some embodiments, the described elements may be configured to reside on a tangible, persistent, addressable storage medium and may be configured to execute on one or more processors. These functional elements may in some embodiments include, by way of example, components, such as software components, object-oriented software components, class components and task components, processes, functions, attributes, procedures, subroutines, segments of program code, drivers, firmware, microcode, circuitry, data, databases, data structures, tables, arrays, and variables. Although the example embodiments have been described with reference to the components, modules and units discussed herein, such functional elements may be combined into fewer elements or separated into additional elements. Various combinations of optional features have been described herein, and it will be appreciated that described features may be combined in any suitable combination. In particular, the features of any one example embodiment may be combined with features of any other embodiment, as appropriate, except where such combinations are mutually exclusive. Throughout this specification, the term “comprising” or “comprises” means including the component(s) specified but not to the exclusion of the presence of others.

Attention is directed to all papers and documents which are filed concurrently with or previous to this specification in connection with this application and which are open to public inspection with this specification, and the contents of all such papers and documents are incorporated herein by reference.

All of the features disclosed in this specification (including any accompanying claims, abstract and drawings), and/or all of the steps of any method or process so disclosed, may be combined in any combination, except combinations where at least some of such features and/or steps are mutually exclusive.

Each feature disclosed in this specification (including any accompanying claims, abstract and drawings) may be replaced by alternative features serving the same, equivalent or similar purpose, unless expressly stated otherwise. Thus, unless expressly stated otherwise, each feature disclosed is one example only of a generic series of equivalent or similar features.

The invention is not restricted to the details of the foregoing embodiment(s). The invention extends to any novel one, or any novel combination, of the features disclosed in this specification (including any accompanying claims, abstract and drawings), or to any novel one, or any novel combination, of the steps of any method or process so disclosed.

1. A method of simulating an electron microscopy image of a sample, the method implemented by a computer comprising a processor and a memory, the method comprising:
obtaining parameters of the electron microscopy, attributes of the sample and respective thresholds of one or more target properties of the simulated electron microscopy image; and
computing, via sub-sampling, the simulated electron microscopy image of size [M×N] pixels of the sample using the obtained parameters of the electron microscopy and the obtained attributes of the sample, according to the obtained respective thresholds of the one or more target properties of the simulated electron microscopy image, wherein the simulated electron microscopy image is due to the interaction of electrons with the sample, as defined by the obtained parameters of the electron microscopy and the obtained attributes of the sample.

2. The method according to claim 1, wherein computing the simulated electron microscopy image of size [M×N] pixels of the sample comprises:
calculating a sparse set of S simulated sub-images, including a first sub-image of size [a×b] pixels wherein a, b∈[2, min {M, N}], of the sample; and
reconstructing the simulated electron microscopy image of size [M×N] pixels of the sample using the sparse set of S simulated sub-images of the sample.

3. The method according to claim 2, comprising sampling the sparse set of S simulated sub-images of the sample.

4. The method according claim 2, wherein calculating the sparse set of S simulated sub-images of the sample comprises independently calculating the sparse set of S simulated sub-images of the sample.

5. The method according to claim 1, wherein computing the simulated electron microscopy image of size [M×N] pixels of the sample comprises:
estimating thermal-diffuse scattering through the sample including modelling the thermal-diffuse scattering through a series of n slices, wherein n≥1, of the sample having a thickness t, wherein modelling the thermal-diffuse scattering through the first slice comprises selecting a set of p frozen phonon configurations, wherein p≥1, thereof.

6. The method according to claim 5, wherein n∝t and/or p∝1/t.

7. The method according to claim 5, wherein computing the simulated electron microscopy image of size [M×N] pixels of the sample comprises:
calculating a sparse set of S simulated sub-images, including a first sub-image of size [a×b] pixels wherein a, b∈[2, min {M, N}], of the sample; and
reconstructing the simulated electron microscopy image of size [M×N] pixels of the sample using the sparse set of S simulated sub-images of the sample, and wherein p∝S.

8. The method according to claim 1, wherein computing the simulated electron microscopy image of size [M×N] pixels of the sample comprises:
determining a number of reciprocal space vectors contributing to the simulated electron microscopy image of size [M×N] pixels of the sample; and
computing the simulated electron microscopy image of size [M×N] pixels of the sample using the determined number of reciprocal space vectors.

9. The method according to claim 1, comprising:
updating the parameters of the electron microscopy, the attributes of the sample and/or the respective thresholds of the one or more target properties of the simulated electron microscopy image; and
computing the simulated electron microscopy image of size [M×N] pixels of the sample using the updated parameters of the electron microscopy and/or the updated attributes of the sample, according to the updated respective thresholds of the one or more target properties of the simulated electron microscopy image.

10. The method according to claim 1, comprising forming a targeted sampling mask which prioritises sampling on atoms of the atoms, using atom locations thereof, wherein the targeted sampling mask includes a bias, R, which allows an atom location to be sampled with a likelihood, P.

11. The method according to claim 1, comprising using a different targeted sampling mask for each frozen phonon configuration.

12. The method according to claim 1, comprising spatially sub-sampling the simulated electron microscopy image, collecting convergent beam electron diffraction, CBED, patterns and forming a sub-sampled image, using a virtual detector.

13. A method of controlling an electron microscope, the method implemented, at least in part, by a computer comprising a processor and a memory, the method comprising:
simulating a simulated electron microscopy image of a sample by:
obtaining parameters of the electron microscopy, attributes of the sample and respective thresholds of one or more target properties of the simulated electron microscopy image; and
computing, via sub-sampling, the simulated electron microscopy image of size [M×N] pixels of the sample using the obtained parameters of the electron microscopy and the obtained attributes of the sample, according to the obtained respective thresholds of the one or more target properties of the simulated electron microscopy image, wherein the simulated electron microscopy image is due to the interaction of electrons with the sample, as defined by the obtained parameters of the electron microscopy and the obtained attributes of the sample; and
acquiring an acquired image of the sample comprising controlling the electron microscope using the parameters of the electron microscopy used for the simulated image.

14. A method of controlling an electron microscope, the method implemented, at least in part, by a computer comprising a processor and a memory, the method comprising:
providing parameters of the electron microscopy;
acquiring a first acquired image of a sample comprising controlling the electron microscope using the provided parameters of the electron microscopy;
simulating a first simulated electron microscopy image of the sample by:
obtaining the parameters of the electron microscopy, attributes of the sample and respective thresholds of one or more target properties of the first simulated electron microscopy image; and
computing, via sub-sampling, the first simulated electron microscopy image of size [M×N] pixels of the sample using the obtained parameters of the electron microscopy and the obtained attributes of the sample, according to the obtained respective thresholds of the one or more target properties of the first simulated electron microscopy image, wherein the first simulated electron microscopy image is due to the interaction of electrons with the sample, as defined by the obtained parameters of the electron microscopy and the obtained attributes of the sample;
comparing the first acquired image and the first simulated image;
adapting the parameters of the electron microscopy based on a result of the comparing; and
acquiring a second acquired image of the sample comprising controlling the electron microscope using the adapted parameters of the electron microscopy.

15. The method according to claim 14, comprising:
simulating a second simulated electron microscopy image of the sample using the adapted parameters of the electron microscopy by:
obtaining the adapted parameters of the electron microscopy, attributes of the sample and respective thresholds of one or more target properties of the second simulated electron microscopy image; and
computing, via sub-sampling, the second simulated electron microscopy image of size [M×N] pixels of the sample using the obtained adapted parameters of the electron microscopy and the obtained attributes of the sample, according to the obtained respective thresholds of the one or more target properties of the second simulated electron microscopy image, wherein the second simulated electron microscopy image is due to the interaction of electrons with the sample, as defined by the obtained adapted parameters of the electron microscopy and the obtained attributes of the sample;
and;
comparing the first acquired image and/or the second acquired image and the second simulated image.

16. (canceled)

17. (canceled)

18. (canceled)
